(19) United States
(12) Patent Application Publication
(10) Pub. No.: US 2009/0319863 A1
(43) Pub. Date: Dec. 24, 2009

(54) ERROR-CORRECTING SYSTEM OF SEMICONDUCTOR MEMORY, ERROR-CORRECTING METHOD, AND MEMORY SYSTEM WITH ERROR-CORRECTING SYSTEM

(76) Inventor: Yutaka SHIRAI, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/406,397

(22) Filed: Mar. 18, 2009

(30) Foreign Application Priority Data
Jun. 24, 2008 (JP) 2008-164951

(51) Int. Cl. H03M 13/29; H03M 13/05; G06F 11/10; G06F 12/02

(52) U.S. Cl. 714/755; 714/785; 714/773; 711/103; 711/E12.008; 714/E11.032

(57) ABSTRACT

An error-correcting system includes a data buffer, a generating unit, a syndrome holding unit, a parity holding unit, and a decoding unit. The data buffer is capable of holding N bits of data. The generating unit generates a syndrome and parity on the basis of the data output from the data buffer. The data buffer outputs n bits in the N bits to a generating unit, while shifting the data bit by bit at intervals of k cycles of a clock. The n bits in the N bits are combination of bits based on a determinant complying with the hamming code. The decoding unit identifies a bit position of an error in the data held in the data buffer using the syndrome held in the syndrome holding unit and causes the data buffer to correct the error.

### CROSS-REFERENCE TO RELATED APPLICATIONS

This application is based upon and claims the benefit of priority from prior Japanese Patent Application No. 2008-164951, filed Jun. 24, 2008, the entire contents of which are incorporated herein by reference.

### BACKGROUND OF THE INVENTION

1. Field of the Invention

This invention relates to an error-correcting system for semiconductor memory, an error-correcting method for semiconductor memory, and a memory system with an error-correcting system. For example, this invention relates to a data-correcting method for a nonvolatile semiconductor memory with memory cells including a charge storage layer and a control gate.

2. Description of the Related Art

A semiconductor memory with an ECC (Error Checking and Correcting) function has been known. The ECC function is to check whether there are any errors in the read-out data and, if an error is found, correcting the error. The ECC function has been disclosed in, for example, Jpn. Pat. Appln. KOKAI Publication No. 2007-080343.

A NAND flash memory has been widely known as a nonvolatile semiconductor memory. In the NAND flash memory, since an error will occur with a certain probability, it is important to use the ECC function.

### BRIEF SUMMARY OF THE INVENTION

An error correction system according to an aspect of the present invention includes:

a data buffer which is capable of holding N bits (N is a natural number not less than 2) of data;

a generating unit which generates a syndrome and parity on the basis of the data output from the data buffer, the data buffer outputting n bits (n is a natural number not less than 1) in the N bits to a generating unit, while shifting the data bit by bit at intervals of k cycles (k is a natural number not less than 1) of a clock, the n bits in the N bits being a combination of bits based on a determinant complying with the hamming code;

a syndrome holding unit which is capable of holding the syndrome generated at the generating unit;

a parity holding unit which is capable of holding the parity generated at the generating unit; and

a decoding unit which identifies a bit position of an error in the data held in the data buffer using the syndrome held in the syndrome holding unit and causes the data buffer to correct the error.

An error-correcting method according to an aspect of the present invention includes:

outputting n bits out of N bits on the basis of a determinant complying with the hamming code (N is a natural number not less than 2, n is a natural number not less than 1), while shifting the N bits of data bit by bit at intervals of k cycles of a clock (k is a natural number not less than 1); and

generating each bit in a syndrome or parity using n bits in the data at intervals of k cycles of the clock.

A memory system according to an aspect of the present invention includes:

the error-correcting system described above;

a NAND flash memory which is capable of holding data; and

a semiconductor memory which is capable of temporarily holding data to be written into the NAND flash memory and data read from the NAND flash memory, the semiconductor memory performing as a buffer memory of the NAND flash memory, the data read from the NAND flash memory being stored into the data buffer and the error-corrected data at the data buffer being stored in the semiconductor memory in loading data operation, the data read from the semiconductor memory being stored into the data buffer and the data stored in the data buffer and the parity generated at the generating unit being programmed in the NAND flash memory in programming data operation.

### BRIEF DESCRIPTION OF THE SEVERAL VIEWS OF THE DRAWING

FIG. 1 is a block diagram of a memory system according to a first embodiment of the invention;

FIG. 2 is a circuit diagram of a memory cell array according to the first embodiment;

FIG. 3 is a block diagram of an ECC unit according to the first embodiment;

FIG. 4 is a diagram to explain the hamming code according to the first embodiment;

FIG. 5 is a block diagram of an ECC buffer according to the first embodiment;

FIG. 6 is a block diagram of a register according to the first embodiment;

FIGS. 7 and 8 are circuit diagrams of the register according to the first embodiment;

FIG. 9 is a circuit diagram of a generator according to the first embodiment;

FIG. 10 is a block diagram of a syndrome holding unit according to the first embodiment;

FIG. 11 is a block diagram of a register according to the first embodiment;

FIG. 12 is a circuit diagram of the register according to the first embodiment;

FIG. 13 is a circuit diagram of a decoding unit according to the first embodiment;

FIG. 14 is a timing chart of various signals in loading data in the memory system according to the first embodiment;

FIGS. 15 and 16 are block diagrams of an ECC buffer according to the first embodiment;

FIGS. 17 to 20 are block diagrams of an ECC unit according to the first embodiment;

FIG. 21 is a timing chart of various signals in programming data in the memory system according to the first embodiment;

FIG. 22 is a block diagram of an ECC unit according to a second embodiment of the invention; and

FIG. 23 is a circuit diagram of a decision circuit according to the second embodiment.

### DETAILED DESCRIPTION OF THE INVENTION

### First Embodiment

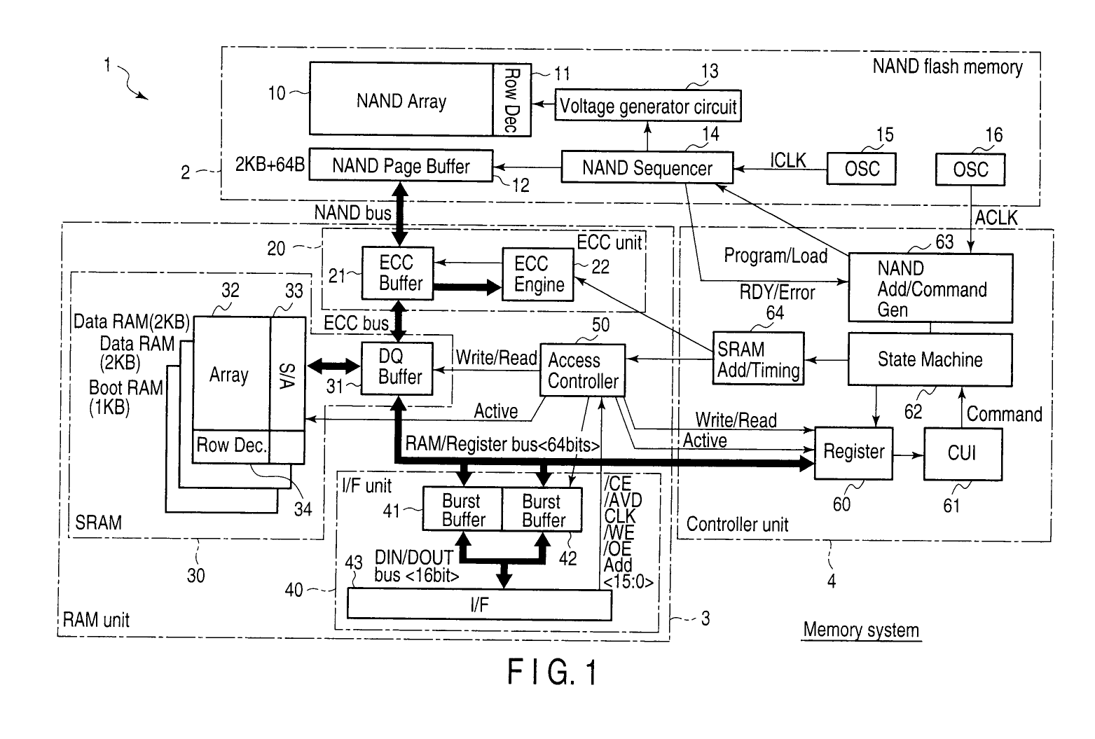

An error-correcting system according to a first embodiment of the invention will be explained using FIG. 1. FIG. 1 is a block diagram of a memory system which realizes a data transfer method according to the first embodiment.

<Overall Configuration of Memory System>

As shown in FIG. 1, the memory system 1 includes a NAND flash memory 2, a RAM unit 3, and a controller unit 4. The NAND flash memory 2, RAM unit 3, and controller unit 4 are formed on the same semiconductor substrate so as to be integrated into one chip. Hereinafter, each of the blocks will be explained in detail.

<NAND Flash Memory 2>

The NAND flash memory 2 functions as a main storage unit of the memory system 1. As shown in FIG. 1, the NAND flash memory 2 includes a memory cell array 10, a row decoder 11, a page buffer 12, a voltage generator circuit 13, a sequencer 14, and oscillators 15, 16.

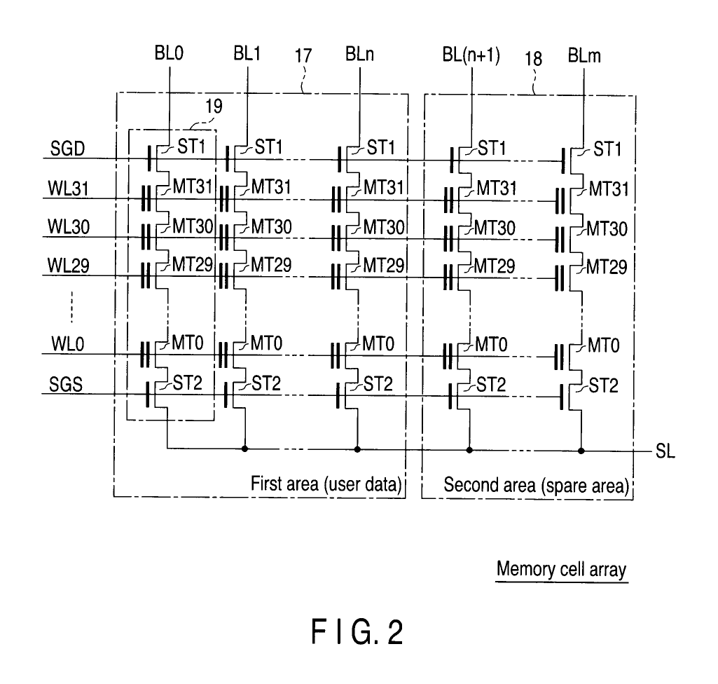

The memory cell array 10 includes a plurality of memory cell transistors capable of holding data. FIG. 2 is a circuit diagram of the memory cell array 10. As shown in FIG. 2, the memory cell array 10 generally includes a first area 17 and a second area 18. The first area 17 holds net data, such as user data, (hereinafter, referred to as main data). The second area 18, which is used as a spare area for the first area 17, holds, for example, error correction information (e.g., parity).

Each of the first area 17 and second area 18 includes a plurality of memory cell units 19. Each of the memory cell units 19 includes, for example, 32 memory cell transistors MT0 to MT31 and select transistors ST1, ST2. Hereinafter, when the memory cell transistors MT0 to MT31 are not distinguished from one another, they are simply referred to as the memory cell transistors MT. Each of the memory cell transistors MT has a stacked gate structure which includes a charge storage layer (e.g., floating gate) formed on a semiconductor substrate with a gate insulating film interposed therebetween and a control gate formed on the charge storage layer with an inter-gate insulating film interposed therebetween. The number of memory cell transistors MT is not limited to 32 and may be 8, 16, 64, 128, 256, or the like. The memory cell transistors MT may have a MONOS (Metal Oxide Nitride Oxide Silicon) structure using a method of causing a nitride film to trap electrons.

The memory cell transistors MT are connected in such a manner that adjacent ones share the drain and source. Moreover, the memory cell transistors are arranged in such a manner that their current paths are connected in series between select transistor ST1 and ST2. The drain of one end side of the memory cell transistors MT connected in series is connected to the source of select transistor ST1. The source of the other end side is connected to the drain of select transistor ST2.

The control gates of the memory cell transistors MT in the same row are connected commonly to any one of word lines WL0 to WL31. The gates of select transistors ST1 in the same row are connected commonly to select gate line SGD. The gates of select transistors ST2 in the same row are connected commonly to select gate line SGS. For ease of explanation, hereinafter, word lines WL0 to WL31 may be simply referred to as word lines WL. The word lines WL and select gate lines SGD, SGS are shared by the first area 17 and second area 18.

In the first area 17, the drains of the select transistors ST1 in the same column are connected commonly to bit lines BL0 to BLn (n is a natural number). In the second area 18, the drains of the select transistors ST1 in the same column are connected equally to bit lines BL(n+1) to BLm (m is a natural number). Bit lines BL0 to BLm may be simply referred to as bit lines BL. The sources of select transistors ST2 are connected commonly to a source line SL. Both of select transistors ST1, ST2 are not necessarily needed. As long as the memory cell unit 19 can be selected, only one of select transistors ST1, ST2 may be provided.

With this configuration, data is simultaneously written into or read from a plurality of memory cell transistors MT connected to the same word line WL. The writing unit or reading unit is termed a page. Moreover, the data in a plurality of memory cell units 19 in the same row are erased simultaneously. The erasing unit is termed a memory block.

Each of the memory cell transistors MT can hold one bit of data according to, for example, a change in the threshold voltage of the transistor depending on the number of electrons injected into the floating gate. Control of the threshold voltage may be so segmented that 2 bits or more of data are held in each of the memory cell transistors MT.

To return to FIG. 1, the explanation of the configuration of the NAND flash memory 2 will be resumed. When data is programmed, read, or erased, the row decoder 11 selects a word line WL and select gate lines SGD, SGS. Then, the row decoder 11 applies the necessary voltages to the word line WL and select gate liens SGD, SGS.

The page buffer 12, which is configured to be capable of holding a page size of data, temporarily holds data given from the RAM unit 3 and writes the data into the memory cell array 10 in a data programming operation. In a read operation, the page buffer 12 temporarily holds the data read from the memory cell array 10 and transfers the data to the RAM unit 3.

The voltage generator circuit 13 steps up or down a voltage supplied from the outside, thereby generating voltages necessary for data programming, reading, and erasing. The voltage generator circuit 13 supplies the generated voltage to, for example, the row decoder 11. The voltage generated at the voltage generator circuit 13 is applied to the word line WL.

The sequencer 14 supervises the overall operation of the NAND flash memory 2. Specifically, when receiving a program instruction (Program), a load instruction (Load), or an erase instruction (not shown) from the controller unit 4, the sequencer 14, in response to this, executes the sequence of data programming, reading, and erasing. Then, according to the sequence, the sequencer 14 controls the operation of the voltage generator circuit 13 and that of the page buffer 12.

The oscillator 15 generates an internal clock ICLK. That is, the oscillator 15 functions as a clock generator. The oscillator 15 supplies the generated internal clock ICLK to the sequencer 14. The sequencer 14 operates in synchronization with the internal clock ICLK.

The oscillator 16 generates an internal clock ACLK. That is, the oscillator 16 functions as a clock generator. The oscillator 16 supplies the generated internal clock ACLK to the controller unit 4 and RAM unit 3. The internal clock ACLK is a reference clock for the operation of the controller unit 4 and RAM unit 3.

<RAM Unit 3>

Referring to FIG. 1, the RAM unit 3 will be explained. The RAM unit 3 includes an ECC unit 20, an SRAM (Static Random Access Memory) 30, an interface unit 40, and an access controller 50. Hereinafter, each of them will be described.

In the memory system 1 of the first embodiment, the NAND flash memory 2 functions as a main storage unit and the SRAM 30 of the RAM unit 3 functions as a buffer. Accordingly, when data is read from the NAND flash memory 2 to the outside, first, the data read from the memory cell array 10 of the NAND flash memory 2 is stored into the SRAM 30 of the RAM unit 3 via the page buffer 12. Thereafter, the data in the SRAM 30 is transferred to the interface unit 40, which then outputs the data to the outside. When data is stored into the NAND flash memory 2, first, data supplied from the outside is stored into the SRAM 30 of the RAM unit 3 via the interface unit 40. Thereafter, the data in the SRAM 30 is transferred to the page buffer 12, which then writes the data into the memory cell array 10.

Hereinafter, the operation from when the data is read from the memory cell array 10 until the data is transferred to the SRAM 30 via the page buffer 12 is referred to as “loading” data. The operation of the data in the SRAM 30 being transferred to the interface 43 via burst buffers 41, 42 (explained later) in the interface unit 40 is referred to as “reading” data.

Furthermore, the operation of data to be stored in the NAND flash memory 2 being transferred from the interface 43 to the SRAM 30 via the burst buffers 41, 42 is referred to as “writing” data. The operation from when the data in the SRAM 30 is transferred to the page buffer 12 until the data is written into the memory cell array 10 of the NAND flash memory 2 is referred to as “programming” data.

<<ECC Unit 20>>

The ECC unit 20 detects and corrects an error in data and generates parity (hereinafter, these processes may be collectively referred to as an ECC process). Specifically, in loading data, the ECC unit detects and corrects an error in the data read from the NAND flash memory 2. In programming data, the ECC unit generates parity for data to be programmed. The ECC unit 20 includes an ECC buffer 21 and an ECC engine 22.

The ECC buffer 21 is connected to the page buffer 12 of the NAND flash memory 2 through a NAND bus and to the SRAM 30 through an ECC bus. In loading data, the ECC buffer 21 not only holds the data transferred via the NAND bus from the page buffer 12 but also transfers the data subjected to the ECC process to the SRAM 30 via the ECC bus. In programming data, the ECC buffer 21 not only holds the data transferred via the ECC bus from the SRAM 30 but also transfers the transferred data and parity to the page buffer 12 via the NAND bus.

The ECC engine 22 carries out the ECC process using the data held in the ECC buffer 21. The ECC engine 22 subjects the main data in units of, for example, N bits (N is a natural number not less than 2, 24 bits in the first embodiment). For example, the ECC engine uses 8 bits of parity for every 24 bits of main data. These numbers of bits are only illustrative. The ECC processing unit and the number of bits of parity are not limited to 24 bits and 8 bits. Suppose the ECC processing unit is 2^{k} bits (k is a natural number). To correct one bit in 2^{k} bits, at least (k+1) bits of parity are needed.

Specifically, in loading data, the ECC engine 22 generates a syndrome using 8 bits of parity for every 24 bits of main data and detects an error using the syndrome. If having detected an error, the ECC engine corrects it. In programming data, the ECC engine generates 8 bits of parity for every 24 bits of main data. The details of the ECC unit 20 will be described later.

<<SRAM 30>>

Next, the SRAM 30 will be explained. In the memory system 1, the SRAM 30 functions as a buffer memory for the NAND flash memory 2. As shown in FIG. 1, the SRAM 30 includes the DQ buffer 31, a plurality of data RAMs (two RAMs in the first embodiment), and a boot RAM.

The DQ buffer 31 writes data into the data RAMs or boot RAM or temporarily holds data in a read operation. As described above, the DQ buffer 31 is configured to be capable of exchanging data with the ECC buffer 21 through the ECC bus. Moreover, the DQ buffer 31 is configured to be capable of exchanging data with the interface unit 40 through a RAM/Register bus having a bus width of, for example, 64 bits.

The boot RAM temporarily holds boot code for starting up, for example, the memory system 1. The capacity of the boot RAM is, for example, 1K bytes. The data RAM temporarily holds data (main data and parity) other than the boot code. The capacity of the data RAM is, for example, 2K bytes. Two units of the data RAM are provided. Each of the data RAM and boot RAM includes a memory cell array 32, a sense amplifier 33, and a row decoder 34.

The memory cell array 32 includes a plurality of SRAM cells capable of holding data. Each of the SRAM cells is connected to a word line and a bit line. Like the memory cell array 10, the memory cell array 32 includes an area for holding main data and an area for holding parity and other data. The sense amplifier 33 senses and amplifies the data read onto a bit line from an SRAM cell. Moreover, the sense amplifier 33 functions as a load in writing the data in the DQ buffer 31 into the SRAM cells. The row decoder 34 selects a word line in the memory cell array 32.

<<Interface Unit 40>>

Next, the interface unit 40 will be explained, referring to FIG. 1. As shown in FIG. 1, the interface unit 40 includes a plurality of burst buffers (two burst buffers in the first embodiment) 41, 42 and an interface 43.

The interface 43, which is capable of connecting with a host unit outside the memory system 1, supervises the input and output of various signals, including data, control signals, and addresses Add, to and from the host unit. Examples of the control signals include a chip enable signal /CE which enables the whole of the memory system 1, an address valid signal /AVD which is for causing an address to be latched, a clock CLK for burst read, a write enable signal /WE which enables a write operation, and an output enable signal /OE which enables the output of data to the outside.

The interface 43 is connected to the burst buffer 41, 42 through a DIN/DOUT having a bus width of, for example, 16 bits. The interface 43 transfers control signals related to a data read request, load request, write request, program request, and the like from the host unit to the access controller 50. Then, in reading data, the interface 43 outputs the data in the burst buffers 41, 42 to the host unit. In writing data, the interface 43 transfers the data supplied from the host unit to the burst buffers 41, 42.

The burst buffers 41, 42 are configured to be capable of exchanging data not only with the DQ buffer 31 and controller unit 4 through the RAM/Register bus but also with the interface 43 through the DIN/DOUT bus. The burst buffer 41, 42 temporarily hold the data supplied from the host unit via the interface 43 or the data supplied from the DQ buffer 31.

<<Access Controller 50>>

The access controller 50 receives the control signal and an address from the interface 43 and controls the SRAM 30 and controller unit 4 so as to carry out an operation to satisfy the request of the host unit.

More specifically, according to the request of the host unit, the access controller 50 brings either the SRAM 30 or a register 60 (described later) of the controller 4 into the active state. Then, the access controller 50 issues a data write command or read command (“Write/Read” shown in FIG. 1) to the SRAM 30. Alternatively, the controller 50 issues a data write command or read command (“Write/Read”) to the register 60 (hereinafter, the command is referred to as a register write command or register read command). As a result of the issue of those commands, the SRAM 30 and controller unit 4 start to operate.

<Controller Unit 4>

Next, the controller unit 4 will be explained, referring to FIG. 1. The controller unit 4 controls the operation of the NAND flash memory 2 and RAM unit 3. That is, the controller unit 4 has the function of supervising the overall operation of the memory system 1. As shown in FIG. 1, the controller unit 4 includes a register 60, a command user interface 61, a state machine 62, an address/command generator circuit 63, and an address/timing generator circuit 64.

The register 60 is for setting the operating state of a function. Specifically, the register 60 sets the operating state of a function according to a register write command or a register read command supplied from the access controller 50. More specifically, for example, in loading data, a load command is set in the register 60. In programming data, a program command is set in the register 60.

When a specific command has been set in the register 60, the command user interface 61 recognizes that a function execute command has been given to the memory system 1. Then, the command user interface 61 issues an internal command signal (“Command” shown in FIG. 1) and outputs it to the state machine 62.

On the basis of the internal command signal given by the command user interface 61, the state machine 62 controls the sequence operation in the memory system 1. The state machine 62 supports many functions, including load, program, and erase. The state machine 62 controls the operation of the NAND flash memory 2 and RAM unit 3 so as to execute those functions. As described above, “load” is the operation of reading data from the NAND flash memory 2 and outputting the data to the SRAM 30. “Program” is the operation of storing RAM data into the NAND flash memory 2. “Erase” is the operation of erasing data in the NAND flash memory 2.

The address/command generator circuit 63 controls the operation of the NAND flash memory 2 under the control of the state machine 62. More specifically, the address/command generator circuit 63 generates an address, a command (“Program/Load” shown in FIG. 1), or the like and outputs it to the NAND flash memory 2. The address/command generator circuit 63 outputs the address and command in synchronization with an internal clock ACLK generated by the oscillator 16.

The address/timing generator circuit 64 controls the operation of the RAM unit 3 under the control of the state machine 62. More specifically, the address/timing generator circuit 64 issues an address and command necessary for the RAM unit 3 and outputs them to the access controller 50 and ECC engine 22.

<Operation of Memory System 1>

Next, the operation of the memory system 1 configured as described above will be explained briefly. In the memory system 1 of the first embodiment, the NAND flash memory 2 and the host unit exchange data via the SRAM 30.

Specifically, when the host unit stores data into the NAND flash memory 2 of the memory system 1, the data is stored temporarily into either the data RAM or boot RAM according to the write command given by the host unit and the address in the SRAM 30. Thereafter, the data stored in the SRAM 30 is programmed in pages simultaneously in the NAND flash memory 2 according to the program command given by the host unit and the address in the NAND flash memory 2.

When the host unit reads data in the NAND flash memory 2, first, the data is read from the NAND flash memory 2 according to the load command, the address of the NAND flash memory 2, and the address of the SRAM 30 given by the host unit and is stored into either the data RAM or boot RAM temporarily. Thereafter, according to the read command and the address of the SRAM 30 given by the host unit, the data held in either the data RAM or boot RAM is read into the host unit via the interface unit 40.

Hereinafter, an example of a load procedure will be explained briefly.

First, the host unit inputs not only the address in the NAND flash memory 2 to be loaded and the address in the SRAM but also a load command to the interface unit 40.

Then, in the memory system 1, the access controller 50 sets the addresses and command in the register 60. Having sensed that the command has been set in the register 60, the command user interface 61 issues an internal command signal. In the case of loading, the command user interface 61 issues a load command.

Receiving the load command from the user interface 61, the state machine 62 starts up. After the necessary initialization of each circuit block, the state machine 62 instructs the address/command generator circuit 63 to issue a sense command to the NAND flash memory 2.

Then, the address/command generator circuit 63 issues a sense command to the sequencer 14 to sense the data in the address set in the register 60.

Receiving the sense command from the address/command generator circuit 63, the sequencer 14 starts up. After the necessary initialization of the NAND flash memory 2, the sequencer 14 senses the specified address. Specifically, the sequencer 14 controls the voltage generator circuit 13, row decoder 11, sense amplifier (not shown), and page buffer 12 and stores the sensed data into the page buffer 12. Thereafter, the sequencer 14 informs the state machine 62 of the completion of the sense operation.

Next, the state machine 62 instructs the address/command generator circuit 63 to issue a transfer command to the NAND flash memory 2. The transfer command is an instruction to transfer data from the NAND flash memory 2 to the RAM unit 3. According to the instruction, the address/command generator circuit 63 issues a transfer command and outputs it to the sequencer 14.

Receiving the transfer command, the sequencer 14 sets the page buffer 12 so as to be capable of transferring data. Under the control of the sequencer 14, the data in the page buffer 12 is transferred to the ECC buffer 21 via the NAND bus.

Moreover, the state machine 62 issues an error correction start control signal to the ECC unit 20. In response to this signal, the ECC unit 20 carries out an ECC process. Then, the data subjected to the ECC process is transferred from the ECC unit 20 to the DQ buffer 31 via the ECC bus.

Then, according to the instruction of the access controller 50, the data in the DQ buffer 31 is written into the memory cell array 32 of the SRAM 30.

This completes the operation of loading the data. Thereafter, the host unit issues a read command via the interface unit 40, thereby reading the data written in the memory cell array 32.

<About the ECC Unit 20>

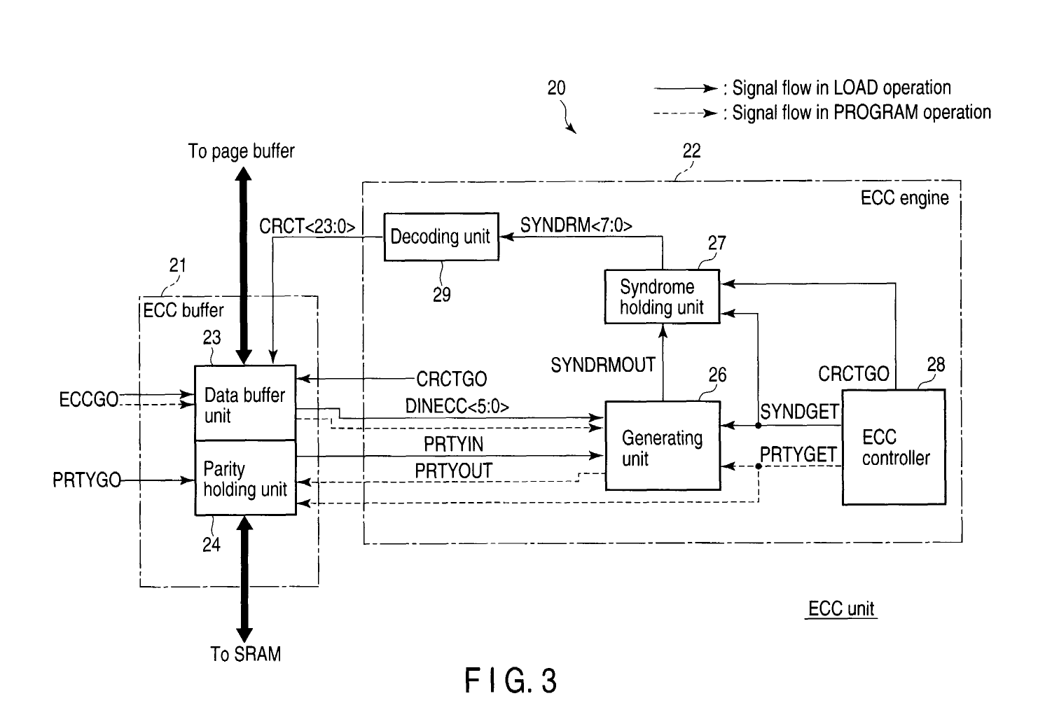

Next, the details of the ECC unit 20 will be explained. FIG. 3 is a block diagram of the ECC unit 20.

<About the ECC Buffer 21>

As shown in FIG. 3, the ECC buffer 21 includes a data buffer unit 23 and a parity holding unit 24.

In loading data, the data buffer unit 23 holds, in units of 24 bits (N=24), main data supplied from the page buffer 12 via the NAND bus. Then, in response to, for example, signal ECCGO supplied from the address/timing generator circuit 64, the data buffer unit transfers the 24-bit main data in units of n bits (n is a natural number, 6 bits in the first embodiment) sequentially to the ECC engine 22. Hereinafter, the n-bit main data is referred to as signal DINECC<5:0>. A combination of n bits is determined on the basis of a determinant complying with the hamming code. Moreover, the data buffer unit 23 corrects any errors that have occurred in the main data according to a 24-bit signal CRCT<23:0> supplied from the ECC engine 22 and transfers the main data to the DQ buffer 31.

In programming data, the data buffer unit 23 holds, in units of 24 bits (N=24), main data supplied from the DQ buffer 1 via the ECC bus. Then, as in loading data, in response to signal ECCGO, the data buffer unit outputs the 24-bit main data in units of 6 bits (n=6) sequentially to the ECC engine 22.

In loading data, the parity holding unit 24 holds, in units of 8 bits, parity supplied from the page buffer 12 via the NAND bus (hereinafter, an 8-bit parity is referred to as parity PRTY). Then, in response to, for example, signal PRTYGO supplied from the address/timing generator circuit 64, the parity holding unit 24 transfers the 8-bit parity to the ECC engine 22 bit by bit sequentially to the ECC engine 22. Hereinafter, the 1-bit parity is referred to as signal PRTYIN.

In programming data, in response to signal PRTYGET supplied from the ECC engine 22, the parity holding unit 24 receives each bit (referred to as signal PRTYOUT) in the parity supplied from the ECC engine 22. When having received signal PRTYOUT eight times, the parity holding unit 24 has got all the bits in parity together, which completes parity PRTY<7:0>. Then, the parity holding unit transfers the resulting parity to the DQ buffer 31.

<About the ECC Engine 22>

As shown in FIG. 3, the ECC engine 22 includes a generating unit 26, a syndrome holding unit 27, an ECC controller 28, and a decoding unit 29.

The generating unit 26 generates a syndrome and parity. Specifically, in loading data, the generating unit, in response to signals ECCGO, PRTYGO supplied from the ECC controller 28, generates one bit (referred to as signal SYNDRMOUT) in an 8-bit syndrome SYNDRM<7:0> using a 6-bit signal DINECC<5:0> supplied from the data buffer unit 23 and a 1-bit signal PRTYIN supplied from the parity holding unit 24. Then, in response to signal SYNDGET, the generating unit transfers signal SYNDRMOUT to the syndrome holding unit 27. Accordingly, an 8-bit syndrome SYNDRM<7:0> is completed by repeating the above process eight times.

In programming data, the generating unit, in response to signal ECCGO supplied from the ECC controller 28, generates one bit (=signal PRTYOUT) in an 8-bit parity PRTY<7:0> using a 6-bit signal DINECC<5:0> supplied from the data buffer unit 23. Then, in response to signal PRTYGET, the generating unit transfers signal PRTYOUT to the parity holding unit 24.

The syndrome holding unit 27 holds signal SYNDRMOUT supplied from the generating unit 26. After an 8-bit syndrome SYNDRM <7:0> is completed by receiving signal SYNDRMOUT eight times, the syndrome holding unit 27 transfers syndrome SYNDRM <7:0> to the decoding unit 29 in response to signal CRCTGO supplied from the ECC controller 28.

The decoding unit 29 generates a 24-bit signal CRCT<23:0> on the basis of syndrome SYNDRM<7:0>. The decoding unit then transfers the generated signal to the data buffer unit 23.

The ECC controller 28 generates the signals ECCGO, PRTYGO, SYNDGET, PRTYGET, CRCTGO, thereby controlling the operations of the generating unit 26, syndrome holding unit 27, and parity holding unit 24.

<About a Hamming Determinant Used in the Generating Unit 26>

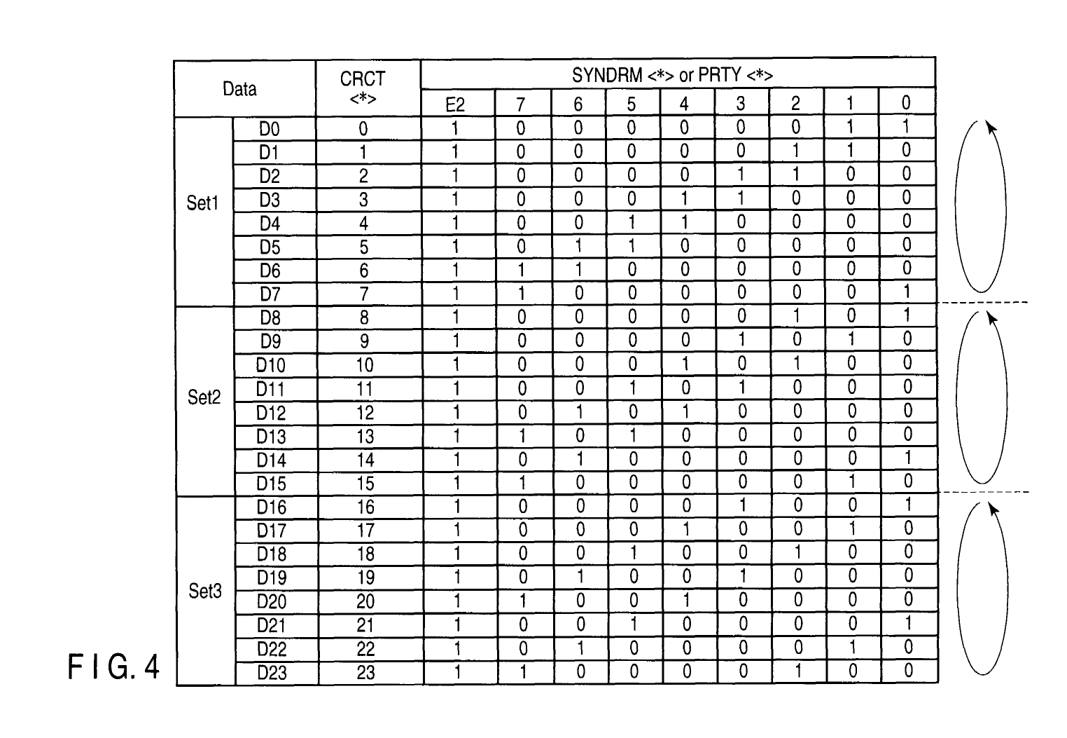

FIG. 4 is a table showing a hamming determinant used in the generating unit 26. Bits D0 to D23 in the main data are shown on the ordinate axis and syndrome SYNDRM<7:0> and parity PRTY<7:0> are shown on the abscissa axis. Numbers 0 to 7 on the abscissa axis correspond to bit SYNDRM<0> to SYNDRM<7> in syndrome SYNDRM<7:0> and bit PRTY<0> to bit PRTY<7> in parity PRTY<7:0>. In FIG. 4, <E2> is related to a decision circuit. The details of the decision circuit will be explained in a second embodiment of the invention.

In FIG. 4, the places where “1” is written represent main data used to generate each bit in syndrome SYNDRM<7:0> and parity PRTY<7:0>.

Specifically, syndrome SYNDRM<7> is generated by a logical XOR operation of bits D6, D7, D13, D15, D20, and D23. Syndrome SYNDRM<6> is generated by a logical XOR operation of bits D5, D6, D12, D14, D19, and D22. Syndrome SYNDRM<5> is generated by a logical XOR operation of bits D4, D5, D11, D13, D18, and D21. The same holds true for the rest. Syndrome SYNDRM<0> is generated by a logical XOR operation of bits D0, D7, D8, D14, D16, and D21. The generating unit 26 transfers each of these syndromes SYNDRM<0> to SYNDRM<7> as signal SYNDRMOUT to the syndrome holding unit 27.

The same holds true for parity. Specifically, parity PRTY<7> is generated so that a logical XOR operation of bits D6, D7, D13, D15, D20, D23 and parity PRTY<7> itself may be zero. Parity PRTY<6> is generated so that a logical XOR operation of bits D5, D6, D12, D14, D19, D22 and parity PRTY<6> itself may be zero. Parity PRTY<5> is generated so that a logical XOR operation of bits D4, D5, D11, D13, D18, D21 and parity PRTY<5> itself may be zero. The same holds true for the rest. Parity PRTY<0> is generated so that a logical XOR operation of bits D0, D7, D8, D14, D16, D21 and parity PRTY<0> itself may be zero. The generating unit 26 transfers each of parity PRTY<0> to PRTY<7> as signal PRTYOUT to the parity holding unit 24.

In FIG. 4, number 0 to number 23 shown in the column CRCT <*> correspond to the individual bits in signal CRCT in a one-to-one correspondence. In FIG. 4, each row shows a combination of syndrome SYNFRM<7:0> for decoding each bit CRCT<0> to CRCT<23>, respectively, and CRCT<0> to CRCT<23> correspond to main data D0 to D23, respectively. One of CRCT<0> to CRCT<23> goes to the high (“H”) level, causing the corresponding main data to be corrected.

Specifically, if syndrome SYNDRM<7> to SYNDRM<2>=“0” and SYNDRM<1> to SYNDRM<0>=“1,” CRCT<0> goes to the “H” level, causing main data D0 to be corrected. If syndrome SYNDRM<7> to SYNDRM<3>=SYNDRM<0>=“0” and SYNDRM<2> to SYNDRM<1>=“1,” CRCT<1> goes to the “H” level, causing main data D1 to be corrected. The same holds true for the rest. If syndrome SYNDRM<6> to SYNDRM<3>=SYNDRM<1> to SYNDRM<0>=“0” and SYNDRM<7>=SYNDRM<2>=“1,” CRCT<23> goes to the “H” level, causing main data D23 to be corrected.

A hamming determinant according to the first embodiment satisfies the following item (1) to item (3) as follows.

As shown in FIG. 4,

(1) Main data is treated in such a manner that the main data is divided into L (L is a natural number not less than 2, 3 in the first embodiment) groups (Set 1 to Set 3) each containing M bits (M is a natural number meeting the expression M<N, 8 bits in the first embodiment).

(2) Main data used in generating each bit in syndrome SYNDRM<7:0> and parity PRTY<7:0> is selected in units of m bits (m is a natural number meeting the equation m×L=n, 2 bits in the first embodiment) from each group.

(3) In each group, 2 bits selected from the main data for generating syndrome SYNDRM<i> (i is 0 to 6) is obtained by shifting 2 bits selected from the main data for generating syndrome SYNDRM<i+1> by one bit. Further, the results of shifting the 2 bits for generating syndrome SYNDRM<0> by one bit coincides with 2 bits for generating syndrome SYNDRM<7>.

That is, 2 bits in the main data to be used for generating syndrome SYNDRM<i> is shifted toward lower bit in proportion to decrease in i. For example, in a group Set 1 including bits D0 to D7, the combination used in generating syndrome SYNDRM<6> is (D6, D5) obtained by shifting (D7, D6) one bit toward D0. A combination used in generating syndrome SYNDRM<5> is (D5, D4), obtained by shifting (D6, D5) one bit toward D0. Finally, a combination used in generating syndrome SYNDRM<0> is (D0, D7) obtained by shifting (D1, D0) one bit toward D0. Further shifting (D0, D7) one bit causes the combination to return to (D7, D6), the combination used in generating syndrome SYNDRM<7>. The same holds true for the remaining groups Set 2 and Set 3.

<The Details of the Configuration of the ECC Buffer 21>

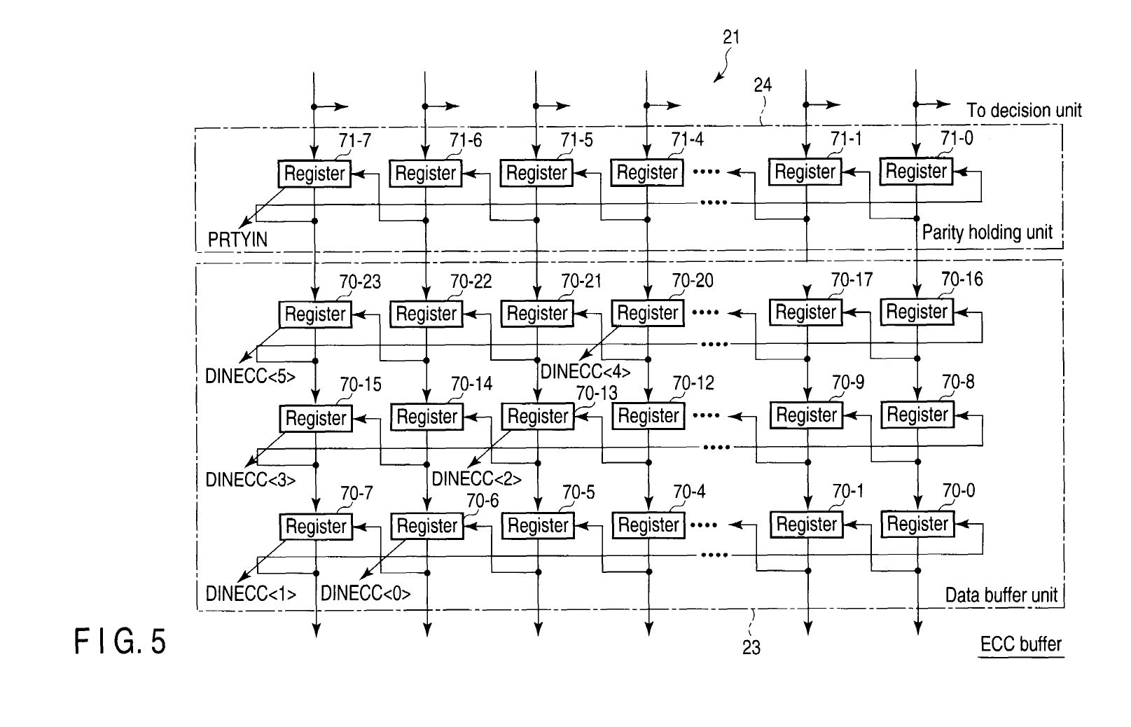

FIG. 5 is a block diagram of the ECC buffer 21 of the first embodiment. As shown in FIG. 5, the ECC buffer 21 includes registers 70-0 to 70-23 and registers 71-0 to 71-7. Hereinafter, when the registers 70-0 to 70-23 are not distinguished, they are referred to as the registers 70. When the registers 71-0 to 71-7 are not distinguished, they are referred to as the registers 71. The registers 70 function as the data buffer unit 23 and the registers 71 function as the parity holding unit 24.

In the data buffer unit 23, registers 70-0 to 70-7 are used for holding group Set 1 in the main data, registers 70-8 to 70-15 are used for holding group Set 2, and registers 70-16 to 70-23 are used for holding group Set 3.

The eight registers 70 which hold bits belonging to the same group are configured to be capable of shifting the bits held therein from register 70-i (i is a natural number including i=0) toward register 70-(i+1). In each group, the register 70 in the last stage is configured to be capable of shifting the bit held therein to the register 70 in the first stage.

More specifically, registers 70-0, 70-8, 70-16 are configured to be capable of shifting the bits held therein to registers 70-1, 70-9, 70-17. Registers 70-1, 70-9, 70-17 are configured to be capable of shifting the bits held therein to registers 70-2, 70-10, 70-18. The same holds true for the rest. Registers 70-7, 70-15, 70-23 in the last stage are configured to be capable of shifting the bits held therein to registers 70-0, 70-8, 70-16 in the first stage.

In the parity holding unit 24, register 71 is configured to be capable of holding each bit in parity PRTY<7:0>. As in the data buffer unit 23, the individual registers 71 are configured to be capable of shifting the bits held therein from register 71-i (i is a natural number including i=0) toward register 71-(i+1). Register 71-7 in the last stage is configured to be capable of shifting the bit held therein to register 71-0 in the first stage.

An input signal to the ECC buffer 21 is first input to registers 71-0 to 71-7. Registers 71-0 to 71-7 are configured to be capable of transferring the bits held therein to registers 70-16 to 70-23, respectively. Registers 70-16 to 70-23 are configured to be capable of transferring the bits held therein to registers 70-8 to 70-15, respectively. Registers 70-8 to 70-15 are configured to be capable of transferring the bits held therein to registers 70-0 to 70-7, respectively. Then, the output signal from the data buffer 21 is output from registers 70-0 to 70-7 to the outside.

Registers 70-6, 70-7, 70-13, 70-15, 70-20, 70-23 are configured to be capable of outputting the bits held therein as the individual bits in signal DINECC<5:0> to the generating unit 26. Register 71-7 is configured to be capable of outputting the bit held therein as signal PRTYIN to the generating unit 26.

The 8-bit data input to the parity holding unit 24 in synchronization with the clock is also supplied to the decision circuit explained in the second embodiment. The decision circuit will be explained in detail in the second embodiment.

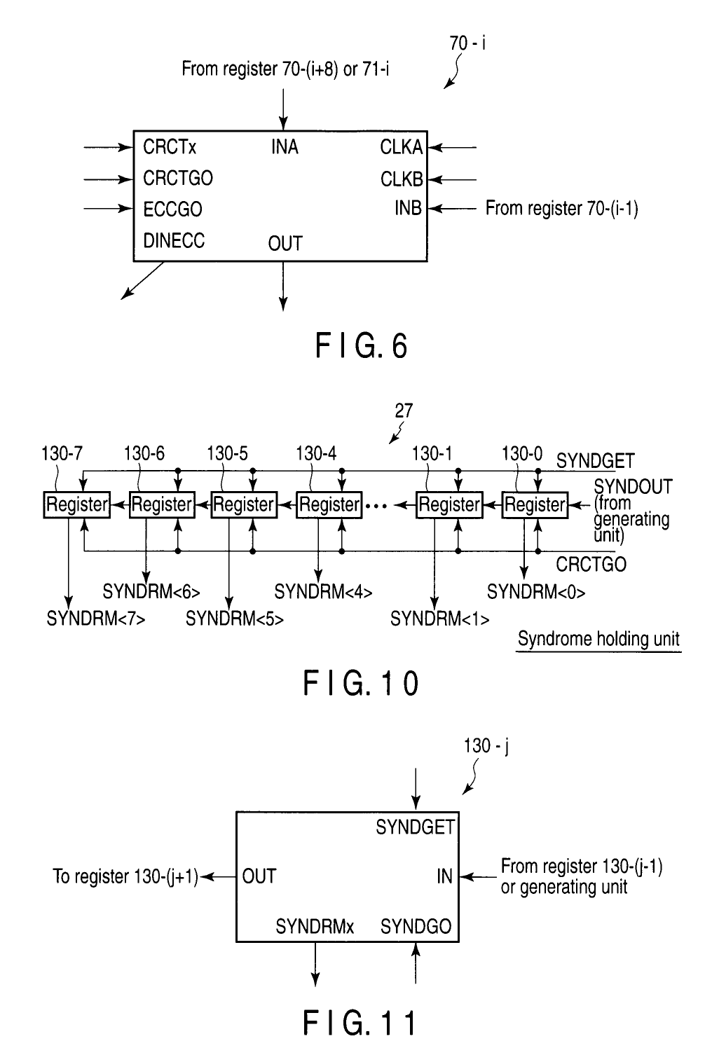

FIG. 6 shows input and output signals to and from register 70-i. As shown in FIG. 6, register 70-i takes in the bits transferred from register 70-(i+8) (in the case of registers 70-0 to 70-15) or register 71-i (in the case of registers 70-16 to 70-23) as input signal INA. Register 70-i further takes in the bit transferred from register 70-(i−1) as input signal INB. If i=0, 8, and 16, register 70-i takes in the bits transferred from registers 70-7, 70-15, 70-23 in the last stage as input signal INB. Register 70-i is configured to be capable of outputting the bit held therein as output signal OUT.

Moreover, clocks CLKA, CLKB are input to register 70-i. Register 70-i operates in synchronization with these clocks. Signals CRCT<i>, CRCTGO are further input to register 70-i. Register 70-i corrects an error on the basis of these signals. In addition, signal ECCGO is input to register 70-i which outputs signal DINECC.

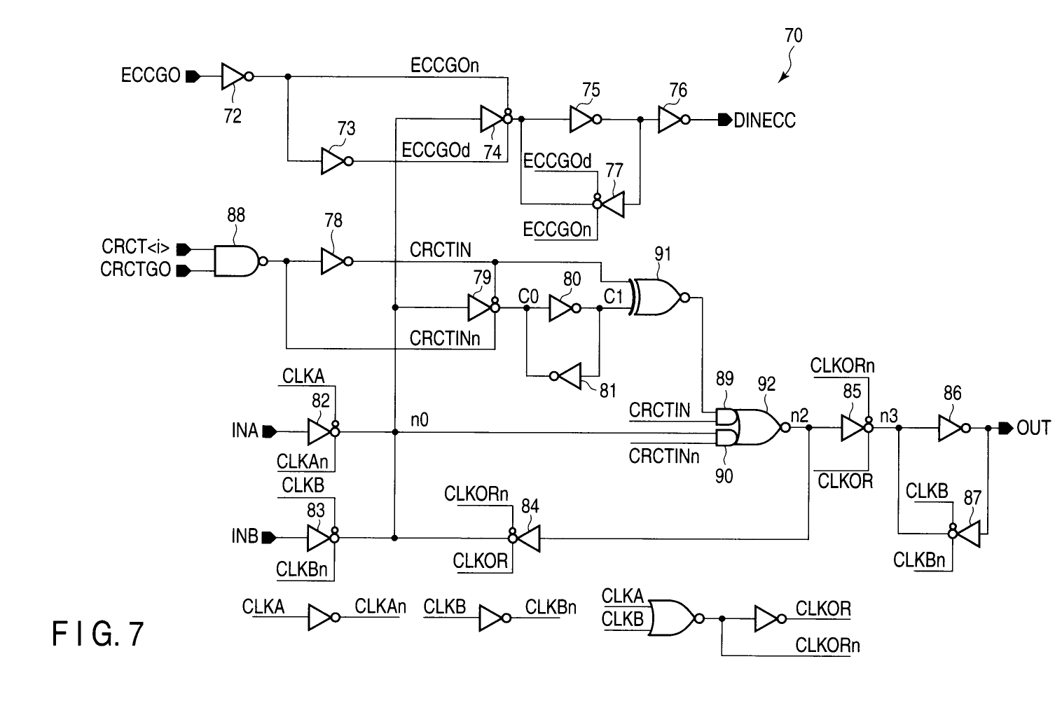

FIG. 7 is a circuit diagram of the register 70 (especially, registers 70-6, 70-7, 70-13, 70-15, 70-20, 70-23 which output signal DINECC). As shown in FIG. 7, register 70 includes inverter 72 to 87, a NAND gate 88, AND gates 89, 80, an XOR gate 91, and a NOR gate 92.

Inverter 72 inverts signal ECCGO and outputs the result as signal ECCGOn. Inverter 73 inverts signal ECCGOn and outputs the result as signal ECCGOd.

NAND gate 88 carries out a NAND operation on signal CRCT<i> and signal CRCTGO and outputs the result as signal CRCTINn. Inverter 78 inverts signal CRCTINn and outputs the result as signal CRCTIN.

Inverter 82 inverts signal INA in synchronization with clocks CLKA, CLKAn and outputs the result to node n0. Clock CLKA is a clock given by, for example the controller unit 4. Clock CLKAn is a signal obtained by inverting clock CLKA. Inverter 83 inverts input signal INB in synchronization with clocks CLKB, CLKBn and outputs the result to node n0. Clock CLKB is also a clock supplied from, for example, the controller unit 4. Clock CLKBn is a signal obtained by inverting clock CLKB.

Inverter 74 inverts the signal at node n0 in synchronization with signals ECCGOn, ECCGOd. Inverter 75 inverts the output of inverter 74. Inverter 77 inverts the output of inverter 75 in synchronization with signals ECCGOd, ECCGOn. The output node of inverter 77 is connected to the input node of inverter 75. Inverter 76 inverts the output of inverter 75 and outputs the result as signal DINECC.

Inverter 79 inverts the signal at node n0 in synchronization with signals CRCTIN, CRCTINn and outputs the result to node C0. Inverter 80 inverts the signal at node C0 and outputs the result to node C1. Inverter 81 inverts the signal at node C1 and outputs the result to node C0. XOR gate 91 carries out an XOR operation of signal CRCTIN and the signal at node C1.

AND gate 89 carries out an AND operation of the output of XOR gate 91 and signal CRCTIN. AND gate 90 carries out an AND operation of the signal at node n0 and signal CRCTINn. NOR gate 92 carries out a NOR operation of the outputs of AND gates 89, 90 and outputs the result to node n2.

Inverter 84 inverts the signal at node n2 in synchronization with signals CLKORn, CLKOR and outputs the result to node n0. Signal CLKORn is obtained by NOR operation on clocks CLKA, CLKB. Signal CLKOR is obtained by inverting signal CLKORn.

Inverter 85 inverts the signal at node n2 in synchronization with signals CLKORn, CLKOR and outputs the result to node n3. Inverter 86 inverts the output of inverter 85. Inverter 87 inverts the output of inverter 86 in synchronization with clocks CLKB, CLKBn and outputs the result to node n3. The output of inverter 86 is output signal OUT.

The configuration of each of the registers 70 (registers 70-0 to 70-5, 70-8 to 70-12, 70-14, 70-16 to 70-19, 70-21, 70-22) which does not output signal DINECC is such that inverters 72 to 77 are eliminated from the configuration of FIG. 7.

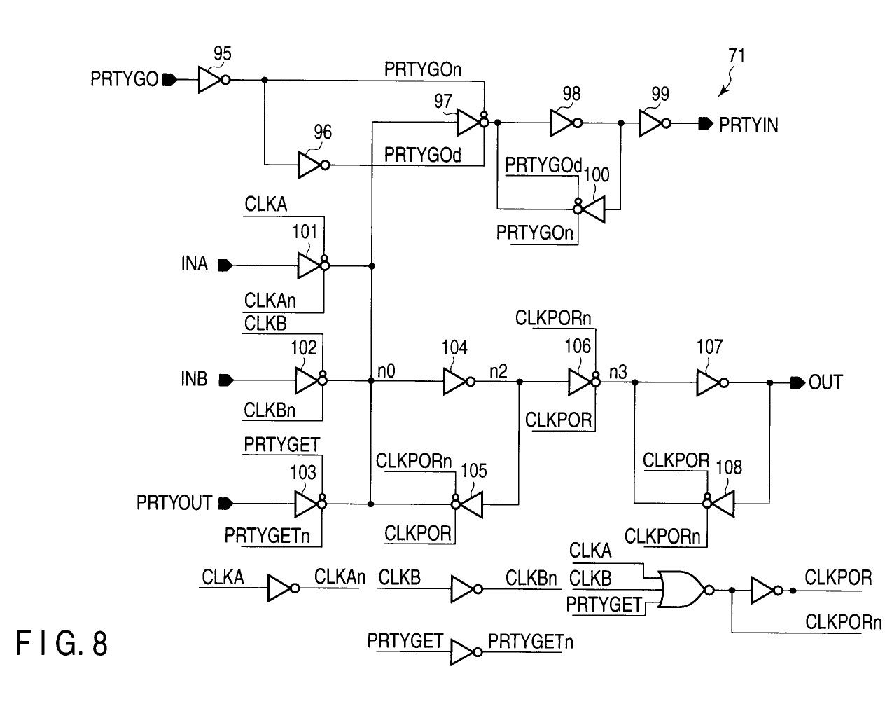

Next, the configuration of register 71 will be explained using FIG. 8. FIG. 8 is a circuit diagram of register 71 (particularly register 71-7 which outputs signal PRTYIN). As shown in FIG. 8, register 71 includes inverters 95 to 108.

Inverter 95 inverts signal PRTYGO and outputs the result as signal PRTYGOn. Inverter 96 inverts signal PRTYGOn and outputs the result as signal PRTYGOd.

Inverter 101 inverts input signal INA in synchronization with signals CLKA, CLKAn and outputs the result to node n0. Inverter 102 inverts input signal INB in synchronization with signals CLKB, CLKBn and outputs the result to node n0. In register 71, input signal INB is the data transferred from register 71-(i−1). Input signal INA is data transferred from outside the ECC buffer 21. Inverter 103 inverts signal PRTYOUT in synchronization with signals PRTYGET, PRTYGETn and outputs the result to node n0. Signal PRTYGETn is obtained by inverting signal PRTYGET.

Inverter 97 inverts the signal at node n0 in synchronization with signals PRTYGOn, PRTYGOd. Inverter 98 inverts the output of inverter 97. Inverter 100 inverts the output of inverter 98 in synchronization with signals PRTYGOd, PRTYGOn. The output node of inverter 100 is connected to the input node of inverter 98. Inverter 99 inverts the output of inverter 98 and outputs the result as signal PRTYIN.

Inverter 104 inverts the signal at node n0 and outputs the result to node n2. Inverter 105 inverts the signal at node n2 in synchronization with signals CLKPORn, CLKPOR and outputs the result to node n0. Signal CLKPORn is obtained by NOR operation on clocks CLKA, CLKB and signal PRTYGET. Signal CLKPOR is obtained by inverting signal CLKPORn.

Inverter 106 inverts the signal at node n2 in synchronization with signals CLKPORn, CLKPOR and outputs the result to node n3. Inverter 107 inverts the output of inverter 106. Inverter 108 inverts the output of inverter 107 in synchronization with signals CLKPOR, CLKPORn and outputs the result to node n3. The output of inverter 107 is the output signal OUT of register 71.

Inverters 95 to 100 may be eliminated from registers 70-0 to 71-6 which do not output signal PRTYIN.

<The Details of the Configuration of the ECC Engine 22>

Next, the circuit configuration of the generating unit 26, syndrome holding unit 27, and decoding unit 29 in the ECC engine 22 will be explained.

<<About the Generating Unit 26>>

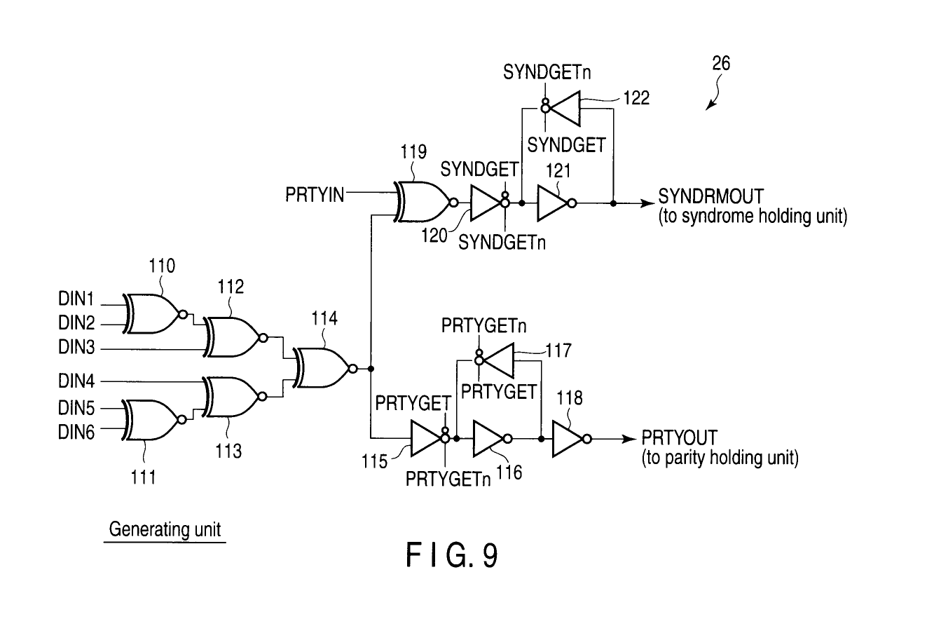

First, the generating unit 26 will be explained. FIG. 9 is a circuit diagram of the generating unit 26. As shown in FIG. 9, the generating unit 26 includes EXCLUSIVE NOT-OR (XNOR) gates 110 to 114, 119 and inverters 115 to 118, 120 to 122.

XNOR gate 110 carries out an XNOR operation of input signals DIN1 and DIN2. Input signals DIN1 and DIN2 are, for example, signals DINECC<0> and DINECC<1> supplied from the data buffer unit 23. XNOR gate 111 carries out the XNOR operation of input signals DIN5 and DIN6. Input signals DIN5 and DIN6 are, for example, signals DINECC<4> and DINECC<5> supplied from the data buffer unit 23. XNOR gate 112 carries out the XNOR operation of the operation result at XNOR gate 110 and input signal DIN3. Input signal DIN3 is, for example, signal DINECC<2> supplied from the data buffer unit 23. XNOR gate 113 carries out the XNOR operation of the operation result at XNOR gate 111 and input signal DIN4. Input signal DIN4 is, for example, signal DINECC<3> supplied from the data buffer unit 23. XNOR gate 114 carries out the XNOR operation of the operation result at XNOR gate 112 and that at XNOR gate 113.

Inverter 115 operates in synchronization with signals PRTYGET, PRTYGETn and inverts the operation result of XNOR gate 114. Inverter 116 inverts the output of inverter 115. Inverter 117 operates in synchronization with signals PRTYGET, PRTYGETn and inverts the output of inverter 116. The output node of inverter 117 is connected to the input node of inverter 116. Inverter 118 inverts the output of inverter 116. The output of inverter 118 is transferred as signal PRTYOUT to the parity holding unit 24.

XNOR gate 119 carries out the XNOR operation of the output of XNOR gate 114 and signal PRTYIN. Inverter 120 operates in synchronization with signals PRTYGET, SYNDGETn and inverts the output of XNOR gate 119. Inverter 121 inverts the output of inverter 120. Inverter 122 operates in synchronization with signals PRTYGET, SYNDGETn and inverts the output of inverter 121. The output node of inverter 122 is connected to the input node of inverter 121. The output of inverter 121 is transferred as signal SYNDRMOUT to the syndrome holding unit 27.

<<About the Syndrome Holding Unit 27>>

Next, the syndrome holding unit 27 will be explained. FIG. 10 is a circuit diagram of the syndrome holding unit 27. As shown in FIG. 10, the syndrome holding unit 27 includes registers 130-0 to 130-7 corresponding to syndrome SYNDRM <7:0>. Hereinafter, when registers 130-0 to 130-7 are not distinguished, they are referred to as the registers 130.

FIG. 11 shows input and output signals to and from the register 130-j (j is a natural number including j=0). The eight registers 130 are configured to be capable of shifting the bits held therein from register 130-j toward register 130-(j+1). Data is input sequentially to register 130-0, starting with syndrome SYNDRM<7>. Each of the registers 130 transfers the bit held therein in synchronization with signal SYNDGET. When all of the registers 130 have stored bits, that is, when registers 130-0 to 130-7 have stored syndromes SYNDRM<0> to SYNDRM<7> respectively, registers 130-0 to 130-7 output syndromes SYNDRM<0> to SYNDRM<7> held therein to the decoding unit 29 in synchronization with signal CRCTGO.

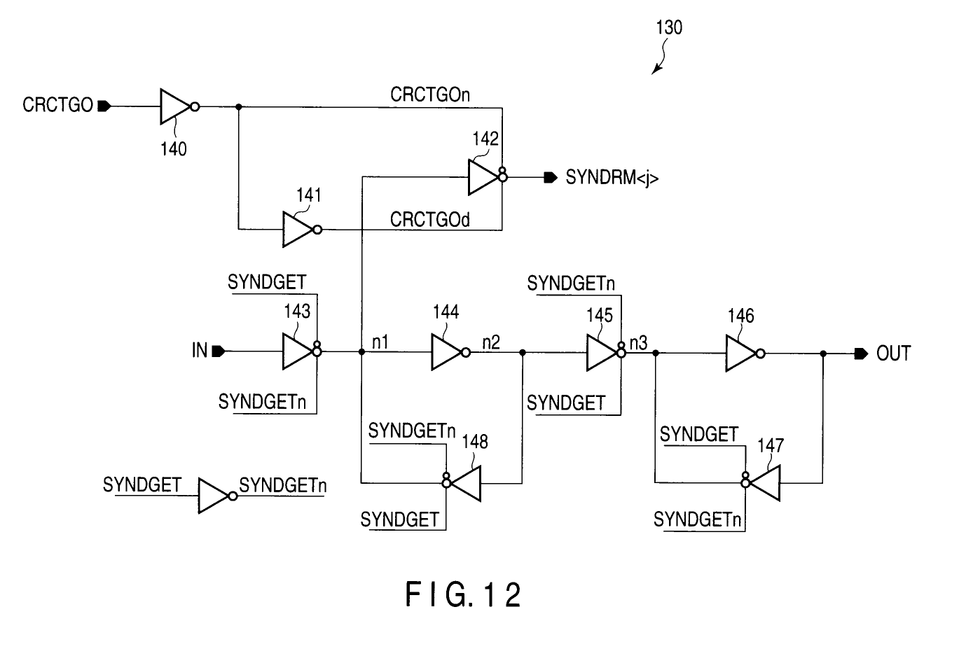

Next, the configuration of register 130 will be explained using FIG. 12. FIG. 12 is a circuit diagram of register 130. As shown in FIG. 12, register 130 includes inverters 140 to 148.

Inverter 140 inverts signal CRCTGO and outputs the result as signal CRCTGOn. Inverter 141 inverts signal CRCTGOn and outputs the result as signal CRCTGOd.

Inverter 143 inverts signal IN in synchronization with signals SYNDGET, SYNDGETn and outputs the result to node n1. Signal SYNDGETn is obtained by inverting signal SYNDGET. In the case of registers 130-1 to 130-7, input signal IN is the output signal OUT of register 130 in the preceding stage. In the case of register 130-0, input signal IN is a signal transferred from the generating unit 26.

Inverter 142 inverts the signal at node n1 in synchronization with CRCTGOn, CRCTGOd. The output of inverter 142 is transferred as syndrome SYNDRM<j> to the decoding unit 29.

Inverter 144 inverts the signal at node n1 and outputs the result to node n2. Inverter 148 inverts the output of inverter 144 in synchronization with SYNDGETn, SYNDGET and outputs the result to node n1. Signal SYNDGETn is obtained by inverting signal SYNDGET.

Inverter 145 inverts the signal at node n2 in synchronization with SYNDGETn, SYNDGET and outputs the result to node n3. Inverter 146 inverts the signal at node n3. Inverter 147 inverts the output of inverter 146 in synchronization with SYNDGET, SYNDGETn and outputs the result to node n3. The output of inverter 146 is transferred as the output signal OUT of register 130 to register 130 in the next stage. In register 130-7 in the last stage, inverters 144 to 148 may be eliminated.

<<About the Decoding Unit 29>>

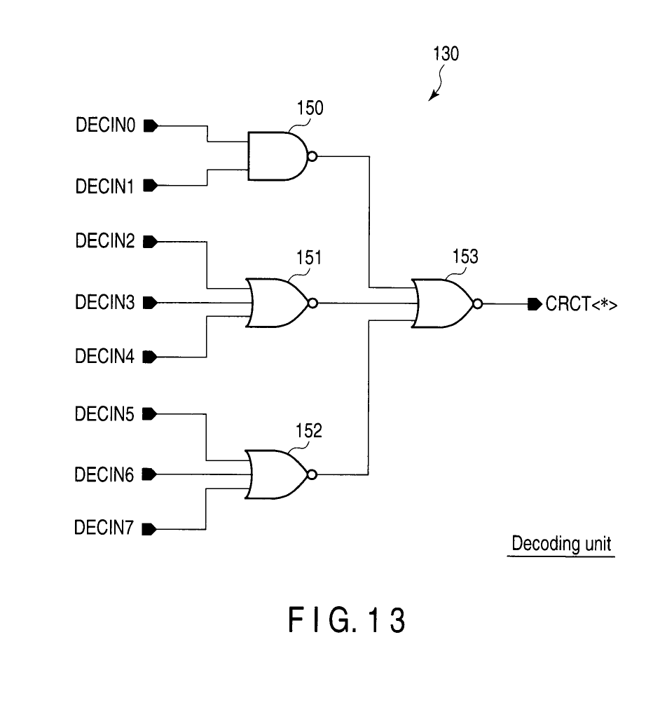

Next, the decoding unit 29 will be explained. FIG. 13 is a circuit diagram of a circuit which generates signal CRCT<i> in the decoding unit 29. As shown in FIG. 13, the decoding unit 29 includes NAND gate 150 and NOR gates 151 to 153.

NAND gate 150 carries out the NAND operation of input signals DECIN0 and DECIN1. NOR gate 151 carries out the NOR operation of input signals DECIN2 to DECIN4. NOR gate 152 carries out the NOR operation of input signals DECIN5 to DECIN7. NOR gate 153 carries out the NOR operation of the operation result of NAND gate 150 and the operation results of NOR gates 151 and 152. The operation result of the NOR gate 153 is output as signal CRCT<*>.

Input signals DECIN0 to DECIN7 differ, depending on the generated signal CRCT<*>. Specifically, in FIG. 4, in syndrome SYNDRM<7:0> corresponding to each signal CRCT<*>, two bits to whose hamming code “1” has been allocated are input signals DECIN0, DECIN1 and the remaining bits are input signals DECIN2 to DECIN7.

For example, when CRCT<0> is generated, syndromes SYNDRM<0> and SYNDRM<1> are input signals DECIN0 and DECIN1 respectively, and syndromes SYNDRM<2> to SYNDRM<7> are input signals DECIN2 to DECIN7 respectively. If CRCT<0> is “1,” bit D0 in the main data is corrected.

When CRCT<8> is generated, syndromes SYNDRM<0> and SYNDRM<2> are input signals DECIN0 and DECIN1 respectively, and syndromes SYNDRM<1>, SYNDRM<3> to SYNDRM<7> are input signals DECIN2 to DECIN7 respectively. If CRCT<8> is “1,” bit D8 in the main data is corrected. The same holds true for the rest.

<Operation of ECC Unit 20>

Next, the operation of the ECC unit 20 configured as described above will be explained.

<Operation in Loading Data>

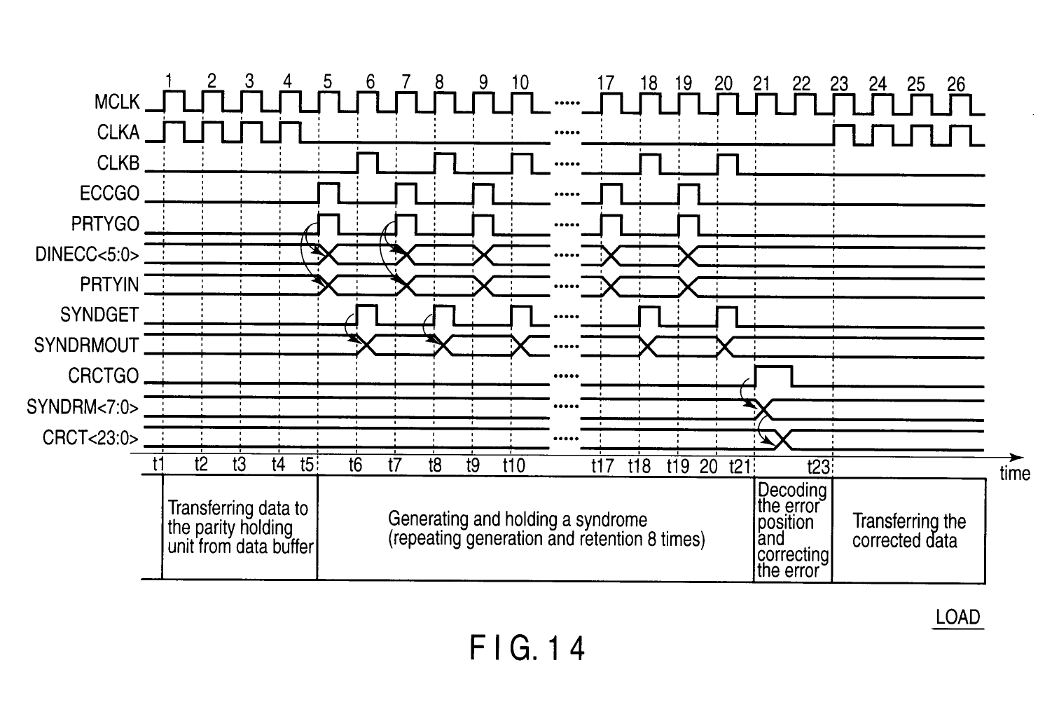

First, the operation of loading data will be explained using FIG. 14. FIG. 14 is a timing chart of main clock MCLK (=ACLK) supplied from, for example, the oscillator 16, clocks CLKA, CLKB, and signals ECCGO, PRTYGO, DINECC<5:0>, PRTYIN, SYNDGET, SYNDRMOUT, CRCTGO, SYNDRM<7:0>, and CRCT<23:0>.

(Step S1)

First, the data read from the memory cell array 10 of the NAND flash memory 2 is transferred from the page buffer 12 to the ECC buffer 21. Hereinafter, an example of transferring 24-bit main data and 8-bit parity will be explained.

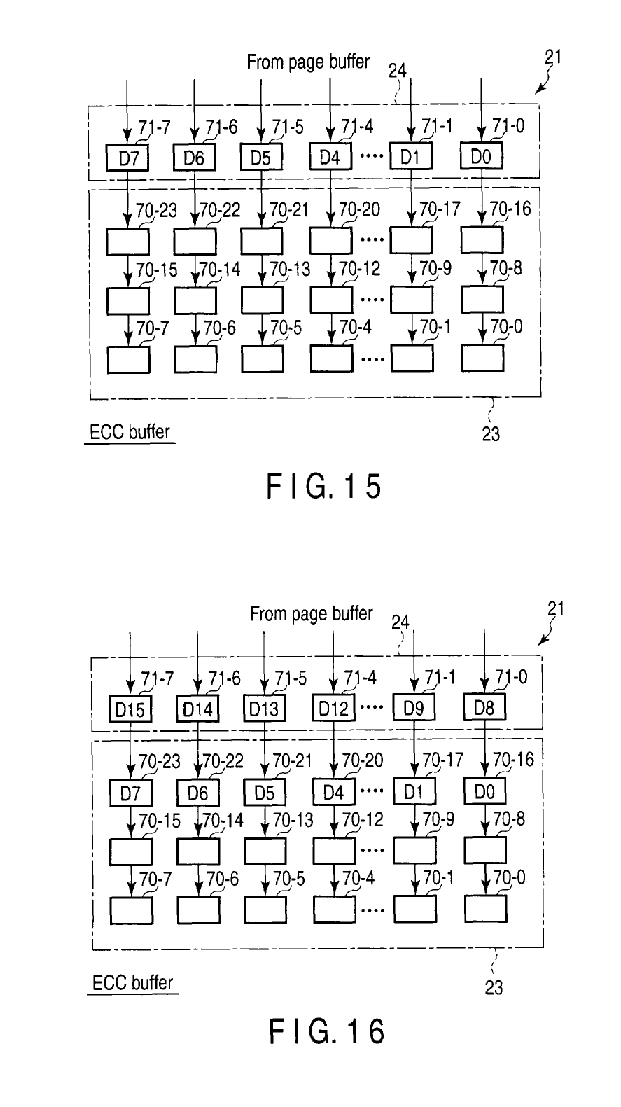

First, in the period between time t1 and time t2, the page buffer 12 transfers bit D0 to bit D7 in the main data to the ECC buffer 21. FIG. 15 is a block diagram of the ECC buffer 21, showing the way the ECC buffer operates in the period from time t1 to time t2. First, bit D0 to bit D7 are transferred to registers 71-0 to 71-7 in the parity holding unit 24, respectively.

Next, in the period between time t2 and time t3, the page buffer 12 transfers bit D8 to bit D15 in the main data to the ECC buffer 21. FIG. 16 is a block diagram of the ECC buffer 21, showing the way the ECC buffer operates in the period from time t2 to time t3. Bit D8 to bit D15 are transferred to registers 71-0 to 71-7 in the parity holding unit 24, respectively. In the period in step S1, clock CLKA synchronizing with clock MCLK is generated and clock CLKB is not generated. Accordingly, registers 70, 71 shift input signal INA (see FIGS. 7 and 8). As a result, the bits D0 to D7 held in registers 71-0 to 71-7 until then are transferred to registers 70-16 to 70-23.

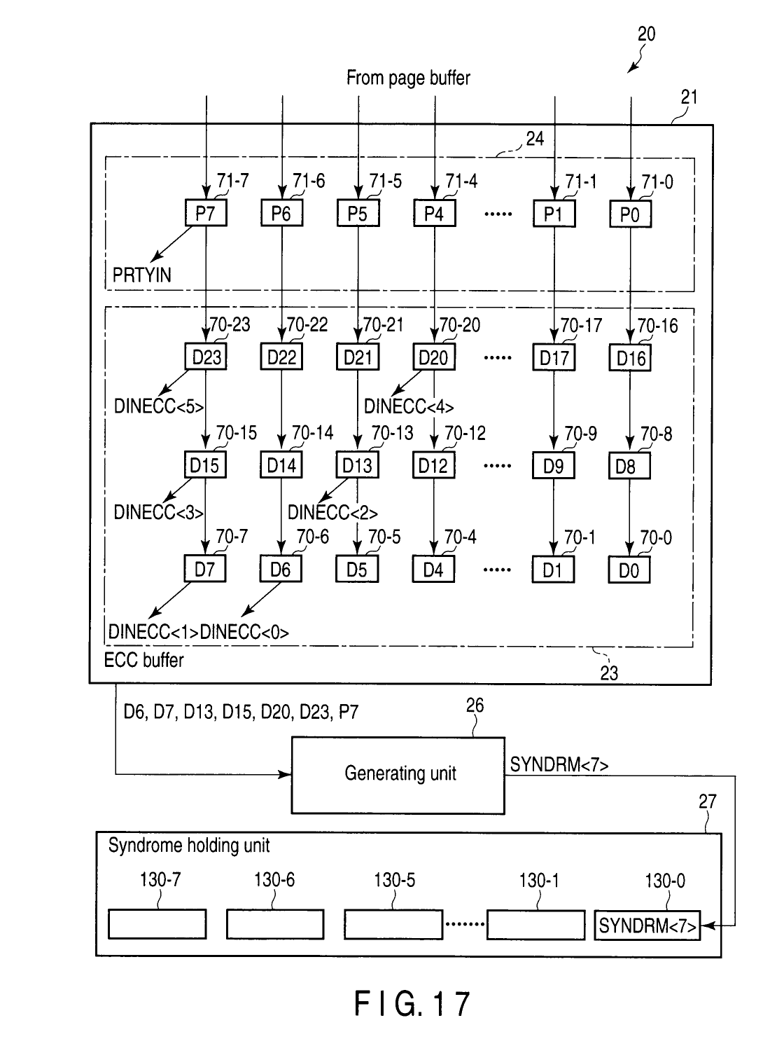

In the period between time t3 and time t4, the page buffer transfers bit D16 to bit 23 in the main data to the parity holding unit 24 and, in the period between time t4 and time t5, transfers parity PRTY<0> to parity PRTY<7> to the parity holding unit 24. FIG. 17 shows the way the ECC buffer 21 operates at time t5. As shown in FIG. 17, input signal INA is transferred sequentially between registers, which completes the transfer of all the bits D0 to D23 in the main data and parity PRTY<0> to PRTY<7> in four clock cycles. That is, bits D0 to D23 in the main data are stored in registers 70-0 to 70-23 respectively, and parity PRTY<0> to PARTY<7> are stored in registers 71-0 to 71-7, respectively. In FIG. 17, parity PRTY<0> to PRTY<7> are written as “P0” to “P7” respectively due to limitations of space.

(Step S2).

Next, the ECC engine 22 starts to generate syndrome SYNDRM<7:0>. When step S2 is started, the generation of clock CLKA is stopped and the generation of signals ECCGO and PRTYGO and that of clock CLKB and signal SYNDGET are alternated in synchronization with main clock MCLK.

First, in the period between time t5 and time t6, signals EECGO, PRTYGO are made high, causing the ECC buffer 21 to transfer signals DINECC<5:0> and PRTYIN to the generating unit 26. This is shown in FIG. 17. As shown in FIG. 17, bits D6, D7, D13, D15, D20, D23 are transferred as DINECC<5:0> and parity PRTY<7> is transferred as PRTYIN. Then, the generating unit 26 generates data corresponding to syndrome SYNDRM<7> using these signals.

Thereafter, signal SYNDGET is made high at time t6, causing syndrome SYNDRM<7> to be transferred as signal SYNDRMOUT to the syndrome holding unit 27. Syndrome SYNDRM<7> is first stored into register 130-0 in the syndrome holding unit 27.

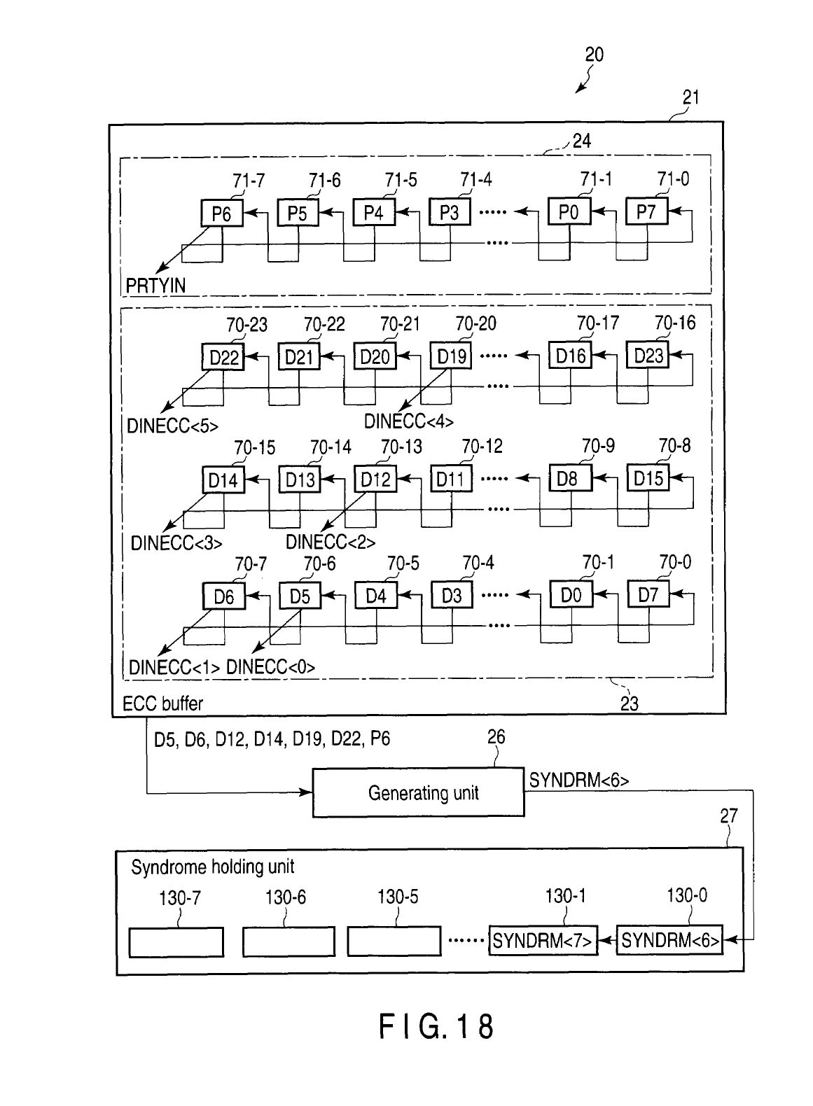

The ECC buffer transfers input signal INB in synchronization with clock CLKB. This is shown in FIG. 18. As shown in FIG. 18, in each group, the main data and parity are shifted. At this time, registers 70-6, 70-7, 70-13, 70-15, 70-20, 70-23, 71-7 have stored bits D5, D6, D12, D14, D19, D22, PRTY<6>, respectively.

Accordingly, in the period between time t7 and time t9, these pieces of data are transferred as signal DINECC<5:0> and PRTYIN to the generating unit 26. Using these signals, the generating unit 26 generates data corresponding to syndrome SYNDRM<6>.

Thereafter, at time t8, signal SYNDGET is made high, causing syndrome SYNDRM<6> to be transferred as signal SYNDRMOUT to the syndrome holding unit 27. In the syndrome holding unit 27, bit shifting is done between the registers 130 in synchronization with signal SYNDRMOUT. Accordingly, syndrome SYNDRM<7> held until then in register 130-0 is transferred to register 130-1 and syndrome SYNDRM<6> is stored in register 130-0.

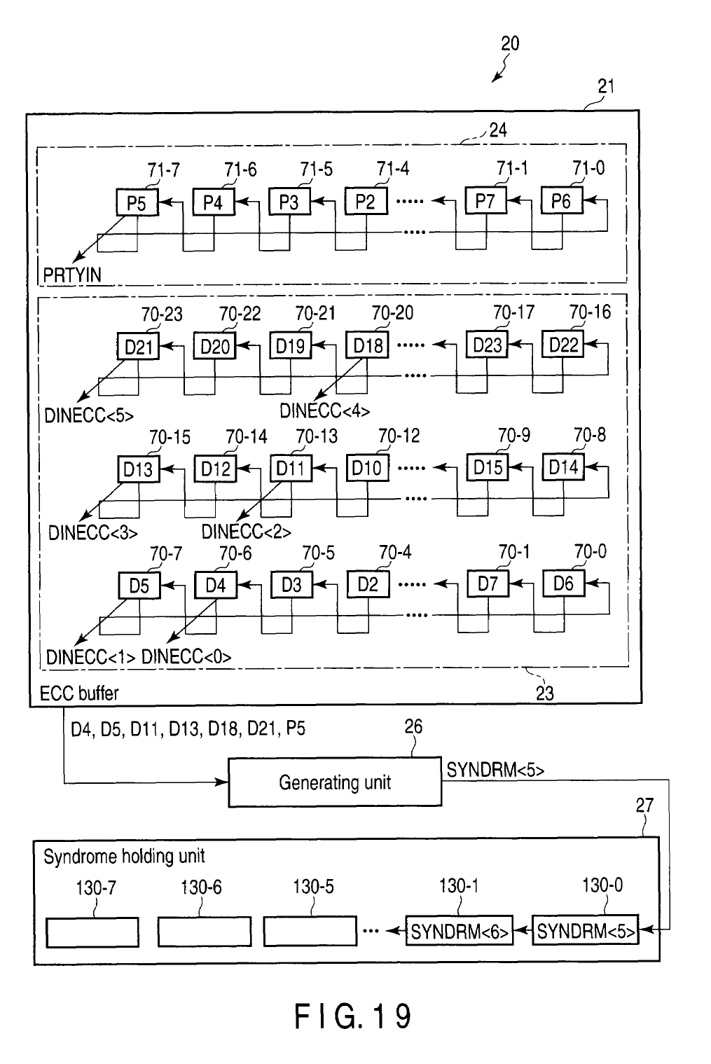

Then, in the ECC buffer 21, the main data and parity are shifted by one bit in each group. This is shown in FIG. 19. At this time, registers 70-6, 70-7, 70-13, 70-15, 70-20, 70-23, 71-7 have stored bits D4, D5, D11, D13, D18, D21, PRTY<5>, respectively.

Accordingly, in the period between time t9 and time t10, these data items are transferred as signal DINECC<5:0> and PRTYIN to the generating unit 26. Using these signals, the generating unit 26 generates syndrome SYNDRM<5>. Thereafter, at time t10, syndrome SYNDRM<5> is transferred to the syndrome holding unit 27.

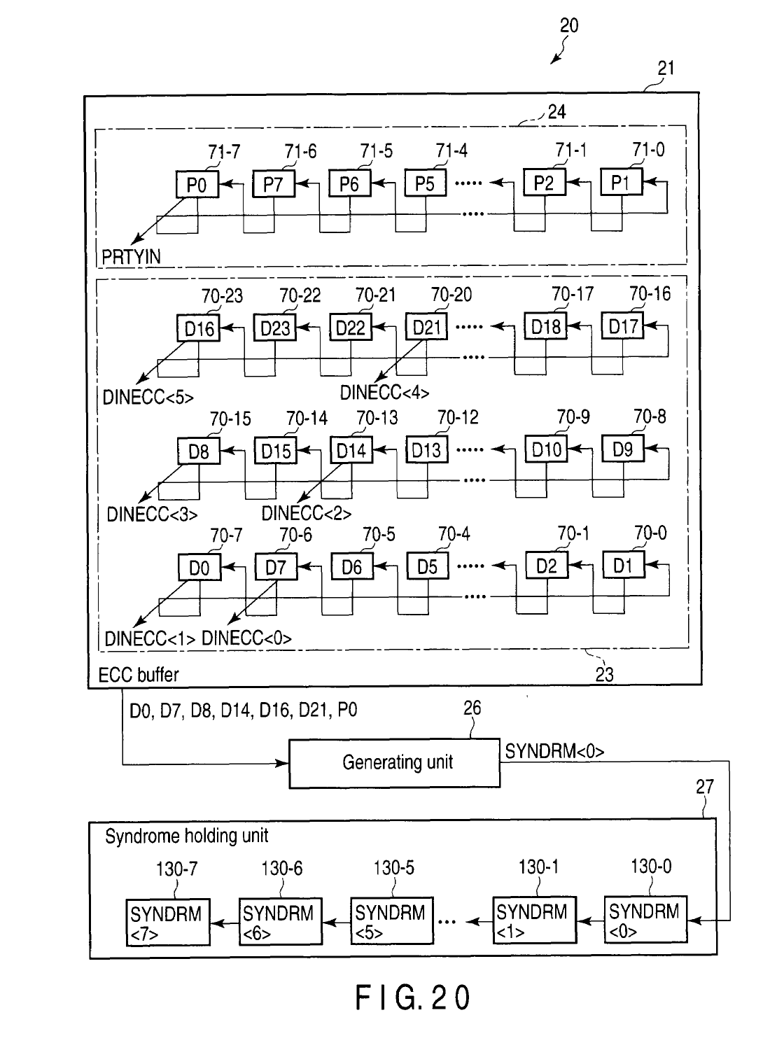

Hereinafter, the same process is repeated a total of eight times. The result is shown in FIG. 20. As shown in FIG. 20, registers 70-6, 70-7, 70-13, 70-15, 70-20, 70-23, 71-7 have stored bits D0, D7, D14, D8, D21, D16, respectively. Using these bits, the generating unit 26 generates syndrome SYNDRM<0>. Then, in the period between time t20 to time t21, registers 130-0 to 130-7 in the syndrome holding unit store syndromes SYNDRM<0> to SYNDRM<7>.

(Step S3)

Next, in step S3, in the 24-bit main data, the position of an error in the main data is decoded and, if there is an error, the error is corrected.

Specifically, at time t21, CRCTGO is made high, causing the decoding unit 29 to decode syndrome SYNDRM<7:0> to generate signal CRCT<23:0> and transfer the generated signal to the main data holding unit 23. Receiving this, the main data holding unit 23 corrects the data.

(Step S4)

Finally, at time t23, the error-corrected main data and parity are transferred from the ECC buffer 21 to the DQ buffer 31 and written into the memory cell array 32 of the SRAM 30.

<Operation in Programming Data>

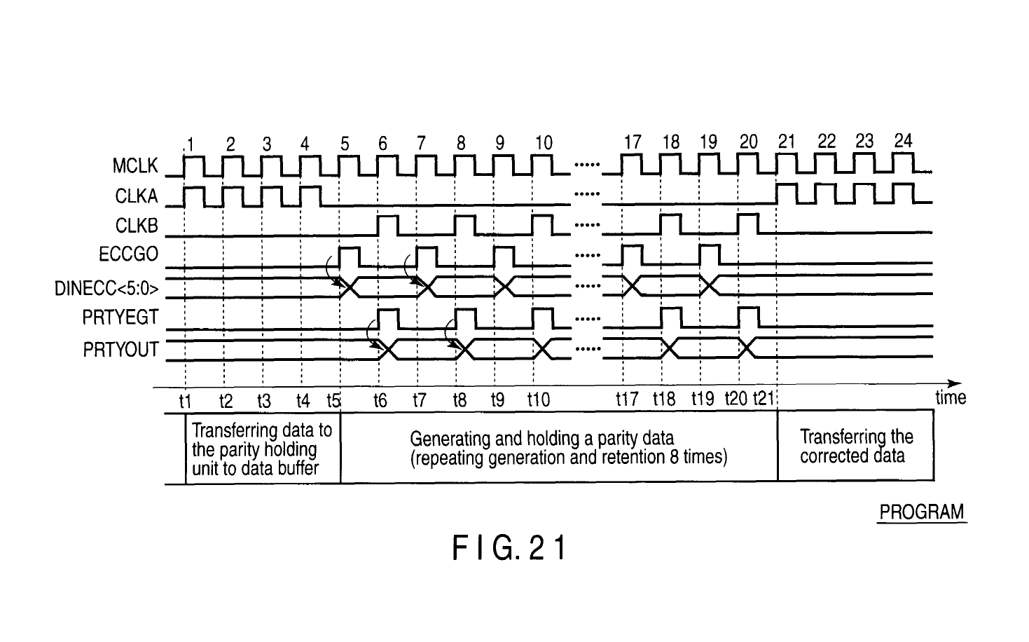

FIG. 21 is a timing chart of main clock MCLK, clocks CLKA, CLKB, and signals ECCGO, DINECC<5:0>, PRTYFET, and PRTYOUT in programming data.

The operation in programming data is almost the same as in loading data. Data programming differs from data loading in that the sender of main data to the ECC buffer 21 is the DQ buffer 31 and the transfer destination from the ECC buffer 21 is the page buffer 12, that the generating unit 26 generates parity, that the transfer of a signal from the parity holding unit 24 to the generating unit 26 is unnecessary, and that the transfer of a signal from the generating unit 26 to the syndrome holding unit 27 is unnecessary.

As shown in FIG. 21, in the period between time t1 and time t5, main data is transferred to the main data holding unit 23 in 4 clock cycles as in loading data. Then, in the period between time t5 and t21, the generating unit 26 generates parity. Thereafter, at time t21, the main data and the generated parity are transferred to the page buffer 12.

<Effect>

As described above, with the error-correcting system of the first embodiment, the main data to be subjected to an error correction is divided into a plurality of groups. In each of the groups, two bits are used for generating syndrome/parity data. The 2-bits are a combination which is obtained by shifting the main data bit by bit for every syndrome/parity and which is configured to be back where it started after all the bits in the syndrome/parity have been generated.

Accordingly, using a shift register in the ECC buffer 21 makes it possible to output main data necessary to generate the individual bits in the syndrome/parity, sequentially in synchronization with the clock. The number of circuits (generating circuits 26) for generating a syndrome and parity is only one. This single generating circuit generates each bit in the syndrome/parity sequentially in synchronization with the clock.

Therefore, even if the number of bits in the main data becomes large, the circuit size of the ECC unit 30 can be decreased, thereby suppressing an increase in the circuit area of the memory system.

Furthermore, using a shift register for the ECC buffer 21 enables main data to be transferred sequentially between the groups. Therefore, the register in the first stage is used for holding parity, which enables the main data and parity to be stored from the base buffer into the ECC buffer 21 sequentially in synchronization with the clock. For example, in the first embodiment, there are threes groups of main data. Therefore, use of four stages of shift registers, including three stages of shift registers for main data and one stage of shift register for parity, enables necessary data to be stored in the ECC buffer 21 in four clock cycles through the 8-bit data bus. This makes it possible to simplify the configuration of the ECC buffer 21 and data transfer control.

### Second Embodiment

Next, an error-correcting system according to a second embodiment of the invention will be explained. The second embodiment is such that the ECC engine 22 further includes a circuit which determines whether the number of errors is even or odd in the first embodiment. Hereinafter, only what differs from the first embodiment will be explained.

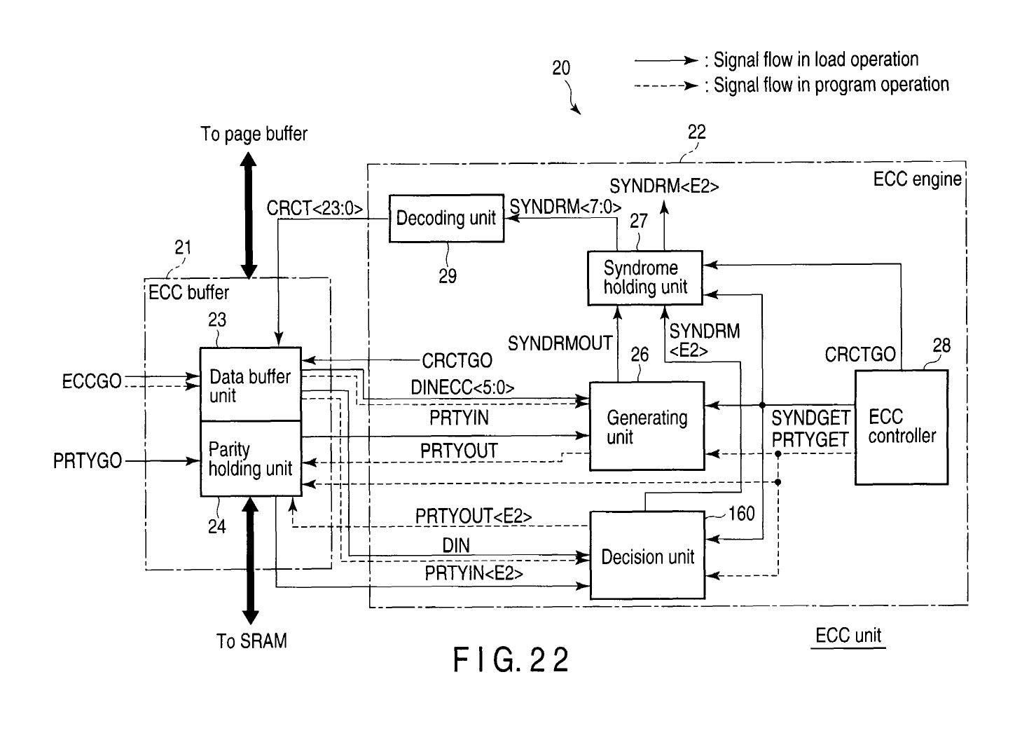

FIG. 22 is a block diagram of an ECC engine 22 according to the second embodiment. As shown in FIG. 22, the ECC engine 22 of the second embodiment further includes a decision unit 160 in the configuration of FIG. 3 explained in the first embodiment.

The decision unit 160 generates a syndrome and parity for determining whether the number of errors is even or odd. Hereinafter, the syndrome and parity are referred to as syndrome<E2> and parity<E2>, respectively. These are information indicating whether the number of errors occurred in the main data is even or odd. The decision unit 160 generates syndrome<E2> and parity<E2> for the result of adding all the bits in the 24-bit main data independently of the aforementioned syndrome SYNDRM<7:0> and parity PRTY<7:0>. This is shown in column “E2” in the table of FIG. 4.

As shown in FIG. 4, for <E2>, “1” is allocated to all the bits D0 to D23. That is, when syndrome SYNDRM<E2> is generated, all of bits D0 to D23 are subjected to XOR operation. Then, for example, in loading data, if the number of errors that have occurred in the main data is odd, syndrome SYNDRM<E2> will be “1.” If the number is odd, syndrome SYNDRM<E2> will be “0.” In programming data, parity PRTY<E2> is generated so that such a result may be obtained.

Then, syndrome SYNDRM<E2> is transferred to the syndrome holding unit 27 and parity PRTY<E2> is transferred to the parity holding unit 24. That is, the decision unit 160 differs from the generating unit 26 in that the former generates a syndrome and parity using all the bits D0 to D23 in the main data.

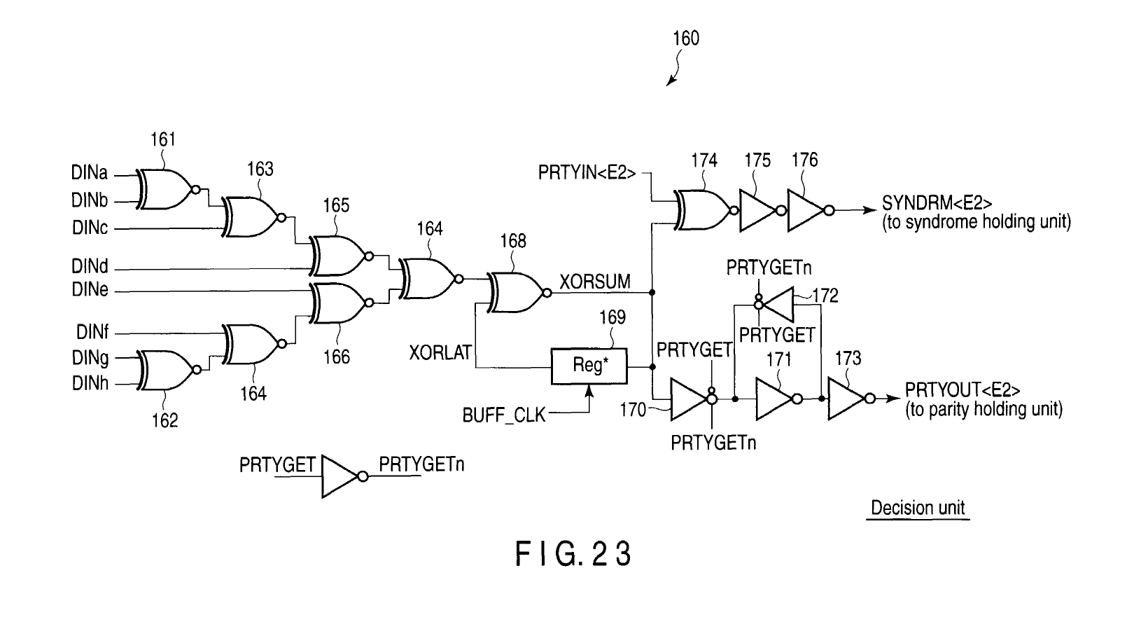

FIG. 23 is a circuit diagram of the decision unit 160. As shown in FIG. 23, the decision unit 160 includes XNOR gates 161 to 168, 174, a register 169, and inverters 170 to 173, 175, 176.

XNOR gate 161 carries out the XNOR operation of input signals DINa and DINb. XNOR gate 162 carries out the XNOR operation of input signals DINg and DINh. XNOR gate 163 carries out the XNOR operation of the operation result at XNOR gate 161 and input signal DINc. XNOR gate 164 carries out the XNOR operation of the operation result at XNOR gate 162 and input signal DINf. XNOR gate 165 carries out the XNOR operation of the operation result at XNOR gate 163 and input signal DINd. XNOR gate 166 carries out the XNOR operation of the operation result at XNOR gate 164 and input signal DINe. XNOR gate 167 carries out the XNOR operation of the operation results at XNOR gates 165 and 166.

XNOR gate 168 carries out the XNOR operation of the operation result at XNOR gate 167 and signal XORLAT output from register 169 and outputs the result as signal XORSUM. Register 169 holds signal XORSUM and outputs it as signal XORLAT to XNOR gate 168. The initial value of register 169 is “0.”

In loading data, XNOR gate 174 carries out the XNOR operation of signal XORSUM and parity PRTYIN<E2> transferred from the parity holding unit 24. The inverter 175 inverts the operation result of XNOR gate 174. Inverter 176 inverts the output of inverter 176 and transfers to the syndrome holding unit 27 the result as syndrome SYNDRM<E2> for determining whether the number of errors is even or odd.

Inverter 170 operates in synchronization with signals PRTYGET, PRTYGETn. In programming data, inverter 170 inverts signal XORSUM. Inverter 171 inverts the output of inverter 170. Inverter 172 operates in synchronization with signals SYNDGET, SYNDGETn and inverts the output of inverter 171. The output node of inverter 172 is connected to the input node of inverter 171. Inverter 173 inverts the output of inverter 171. The output of inverter 173 is transferred as signal PRTYOUT<E2> to the parity holding unit 24.

With the above configuration, each of input signals DINa to DINh corresponds to any bit in the main data. That is, 8 bits in the 24-bit main data are allocated to input signals DINa to DINh. The operation result XORSUM of these bits is held in register 169 in synchronization with clock BUFF_CLK.

Then, another 8 bits in the 24-bit main data are allocated to input signals DINa to DINh. The operation result SORSUM of these bits and signal XORLAT held in the register is written over register 169 in synchronization with clock BUFF_CLK.

Finally, the remaining 8 bits are allocated to input signals DINa to DINh. The operation result XORSUM of these bits and signal XORLAT held in the register is written over register 169 in synchronization with clock BUFF_CLK.

<Effect>

As described above, with the error-correcting system of the second embodiment, the decision unit 160 determines whether the number of error bits is even or odd.

With a system which corrects a 1-bit error using the hamming code, if not less than 2-bits error have occurred, the error cannot be corrected properly. However, use of means for determining whether the number of errors is even or odd makes it possible to grasp the reliability of error correction. Usually, errors occur in one bit or two bits. Accordingly, referring to the result of the determination at the decision unit 160 makes it possible to determine whether the number of error bits is one and the error has been corrected properly, whether no error has occurred, or whether the number of error bits is not less than two and the errors have not been corrected properly. Accordingly, the operation reliability of the memory system can be improved.

As explained in the first embodiment, in the second embodiment, the main data is divided into a plurality of groups. When all the bits in the main data are added at the decision unit 160, the main data is transferred group by group to the decision circuit 160. Each time a group is transferred, the decision unit 160 performs an XOR operation on the group. The decision unit 160 updates the XOR operation result each time a new group is input. Accordingly, there is no need to wait to perform operations until all the bits in the main data have been input, which makes the operations faster. Moreover, the circuit necessary for the XOR operation of one group can perform the XOR operation on all the bits in the main data, which suppresses an increase in the area of the operational circuit.

As described above, an error-correcting system according to each of the first and second embodiments includes a data buffer 23 which is capable of holding N bits (N is a natural number not less than 2, for example, 24 bits) of data D0 to D23; a generating unit 26 which generates a syndrome and parity on the basis of DINECC<23:0> output from the data buffer 23; a syndrome holding unit 27 which is capable of holding syndrome SYNDRM<7:0> generated at the generating unit 26; a parity holding unit 24 which is capable of holding parity PRTY<7:0> generated at the generating unit 26; and a decoding unit 29 which identifies a bit position of an error in the data held in the data buffer 23 using syndrome SYNDRM<7:0> held in the syndrome holding unit 27 and causes the data buffer 23 to correct the error. The data buffer 23 outputting n bits (n is a natural number not less than 1, for example, 6 bits) DINECC<5:0> in the N bits to a generating unit 26, while shifting the data D0 to D23 bit by bit at intervals of k cycles (k is a natural number not less than 1, for example, one cycle) of a clock. The n bits DINECC <5:0> in the N bits is a combination of bits based on a determinant complying with the hamming code.

In the first and second embodiments, a case where one clock is needed when one group in the main data is transferred to the ECC buffer 21 has been explained. In addition, the embodiments may be applied to a case where a plurality of clock cycles are needed.

The number of groups into which the main data is divided is not restricted to 3. When the number of bits in the main data is increased without increasing the number of bits in parity, the number of groups into which the main data is divided has to be increased. The number of bits necessary for parity is (k+1) bits if the number of bits in the main data is 2k bits as described above.

Furthermore, in the first and second embodiments, a case where the NAND flash memory 2, RAM unit 3, and controller unit 4 have been integrated into one chip has been explained. A concrete example of such a memory system 2 is a “OneNAND” (registered trademark) flash memory. However, the embodiments are not limited to a one-chip configuration. For instance, the NAND flash memory 2, RAM unit 3, and controller unit 4 may be realized by separate semiconductor chips.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An error-correcting system comprising:
a data buffer which is capable of holding N bits (N is a natural number not less than 2) of data;
a generating unit which generates a syndrome and parity on the basis of the data output from the data buffer, the data buffer outputting n bits (n is a natural number not less than 1) in the N bits to a generating unit, while shifting the data bit by bit at intervals of k cycles (k is a natural number not less than 1) of a clock, the n bits in the N bits being a combination of bits based on a determinant complying with the hamming code;
a syndrome holding unit which is capable of holding the syndrome generated at the generating unit;
a parity holding unit which is capable of holding the parity generated at the generating unit; and
a decoding unit which identifies a bit position of an error in the data held in the data buffer using the syndrome held in the syndrome holding unit and causes the data buffer to correct the error.

2. The system according to claim 1, wherein the generating unit generates any bit in the syndrome using the n-bit output from the data buffer at intervals of k cycles of the clock and outputs the generated bit to the syndrome holding unit, and
the syndrome holding unit outputs the syndrome to the decoding unit after having received all the bits in the syndrome from the generating unit.

3. The system according to claim 1, wherein the generating unit generates any bit in the parity using the n-bit output from the data buffer at intervals of k cycles of the clock and outputs the generated bit to the parity holding unit, and
the parity holding unit outputs the parity to a target, in which the data is to be written, after having received all the bits in the parity from the generating unit.

4. The system according to claim 1, wherein the data buffer divides the data into L groups (L is a natural number not less than 2) each including M bits (M<N), holds the groups, and outputs to the generating unit the n bits obtained by selecting m bits from each of the groups (m is a natural number and meets the equation m×L=n), while shifting the data in the L groups, and
the generating unit generates any bit in the syndrome or parity based on the m bits selected from each of the L groups.

5. The system according to claim 1, further comprising a decision circuit which determines whether the number of erroneous bits is even or odd in the data held in the data buffer and which generates a syndrome or parity using all the bits in the data and performs operations in units of the groups to generate the syndrome or parity.

6. The system according to claim 4, wherein the data buffer includes L register groups each including M registers,
the L register groups correspond to the L groups in a one-to-one correspondence,
the M registers in each of the L register groups hold any bit in the M bits belonging to each group,
the m bits held in m registers in the M registers in each of the register groups are output to the generating unit, and
the bits held in the registers in each of the register groups are transferred between the registers at intervals of k cycles of the clock.

7. An error-correcting method comprising:
outputting n bits out of N bits on the basis of a determinant complying with the hamming code (N is a natural number not less than 2, n is a natural number not less than 1), while shifting the N bits of data bit by bit at intervals of k cycles of a clock (k is a natural number not less than 1); and
generating each bit in a syndrome or parity using n bits in the data at intervals of k cycles of the clock.

8. The method according to claim 7, further comprising:
when the syndrome is generated, accumulating each bit in the syndrome; and
after all the bits in the syndrome have been accumulated, identifying a bit position of an error in the N-bit data using the syndrome and, if there is an error, correcting the error.

9. The method according to claim 7, further comprising:
when the parity is generated, accumulating each bit in the parity; and
after all the bits in the parity have been accumulated, programming the N-bit data and the parity in a NAND flash memory.

10. The method according to claim 7, wherein the outputting n bits includes storing the data into a shift register in units of L groups (L is a natural number not less than 2) each containing M bits (M<N) and outputting m bits (m is a natural number and meets the equation m×L=n) in each of the groups by shifting the data bit by bit in each of the groups at intervals of k cycles of the clock.

11. A memory system comprising:
the error-correcting system recited in claim 1;
a NAND flash memory which is capable of holding data; and
a semiconductor memory which is capable of temporarily holding data to be written into the NAND flash memory and data read from the NAND flash memory, the semiconductor memory performing as a buffer memory of the NAND flash memory, the data read from the NAND flash memory being stored into the data buffer and the error-corrected data at the data buffer being stored in the semiconductor memory in loading data operation, the data read from the semiconductor memory being stored into the data buffer and the data stored in the data buffer and the parity generated at the generating unit being programmed in the NAND flash memory in programming data operation.

12. The system according to claim 11, wherein the error-correcting system, the NAND flash memory, and the semiconductor memory are formed on the same semiconductor substrate.

13. The system according to claim 11, further comprising an interface unit which manages an exchange of the data with the outside,
wherein the data loaded from the NAND flash memory is output from the interface unit to the outside via the semiconductor memory, and
the data to be programmed in the NAND flash memory is input to the interface unit from the outside and is stored into the semiconductor memory via the interface unit.

14. The system according to claim 13, further comprising a controller which instructs the NAND flash memory to program or load the data,
wherein the error-correcting system, the NAND flash memory, the semiconductor memory, the interface unit, and the controller are formed on the same semiconductor substrate.

15. The system according to claim 14, wherein, when the data is read from the NAND flash memory to the outside,
the interface unit receives a load instruction externally supplied, causing the controller to instruct the NAND flash memory to load the data, and
after the data is loaded from the NAND flash memory into the semiconductor memory, the interface unit receives a read instruction externally supplied, causing the semiconductor memory to output the data to the outside via the interface unit.

16. The system according to claim 14, wherein, when the data is written into the NAND flash memory,
the interface unit receives an externally supplied write instruction and the data, causing the semiconductor memory to hold the data, and
after the data is held in the semiconductor memory, the interface unit receives an externally supplied program instruction, causing the controller to instruct the NAND flash memory to program the data.
